(19) United States
(12) Patent Application Publication
(10) Pub. No.: US 2026/0013070 A1
(43) Pub. Date: Jan. 8, 2026

(54) POWER ELECTRONIC SYSTEM WITH THERMALLY SEGREGATED AREAS

(71) Applicant: Frank Shum, Sunnyvale, CA (US)

(72) Inventor: Frank SHUM, Sunnyvale, CA (US)

(21) Appl. No.: 19/260,671

(22) Filed: Jul. 7, 2025

Related U.S. Application Data
(60) Provisional application No. 63/668,335, filed on Jul. 8, 2024.

(51) Int. Cl. H05K 7/20; H05K 5/02

(52) U.S. Cl. CPC H05K 7/20136; H05K 5/0217

(57) ABSTRACT

The present disclosure discloses the power electronic system comprising at least one enclosure enclosing at least a first area and a second area, wherein the first area has a lower temperature than the second area. The power electronic system further comprises the first area comprising a first set of electronic components, and the second area comprising a second set of electronic components and a third set of electronic components. Further, the first set of electronic components comprises at least one thermal-sensitive component that is more temperature-sensitive than either of the second set of electronic components and the third set of electronic components. Furthermore, the first area is thermally isolated from the second area. Further, the second set of electronic components provides power to the first set electronic components, which in turn provides power to the third set electronic components, thereby physically separating the electrically intermediate components for enhanced thermal protection.

### TECHNICAL FIELD

The present disclosure generally relates to a power electronic system. In particular, the present disclosure relates to the power electronic system configured with different thermally segregated areas to achieve enhanced overall reliability and performance through improved thermal management.

### BACKGROUND

The subject matter discussed in the background area should not be assumed to be prior art merely because of its mention in the background area. Similarly, a problem mentioned in the background area or associated with the subject matter of the background area should not be assumed to have been previously recognized in the prior art. The subject matter in the background area merely represents different approaches, which in and of themselves may correspond to implementations of the claimed technology.

Power electronic systems, such as LED drivers, solar inverters, and various types of power converters and amplifiers, are widely used across consumer, industrial, and automotive applications to regulate and control the flow of electrical energy. Such power electronic systems typically include semiconductor devices, control circuits, and passive components arranged to convert and condition power efficiently.

However, a persistent challenge in the design and operation of such systems is the reduction in operational lifespan due to thermal stress. Many components within the power electronic system, such as power transistors, gate drivers, Metal-Oxide-Semiconductor Field-Effect Transistors (MOSFETs), electrolytic capacitors, and current sense resistors are sensitive to elevated temperatures. Among such components, the electrolytic capacitors are highly temperature-sensitive components. When such components are exposed to continuous or transient thermal overload, it can result in early degradation or permanent damage, leading to failure of the entire system.

In particular, localized hotspots in circuits of the power electronic system often cause certain temperature-sensitive components to experience higher thermal stress than others. Over time, this thermal imbalance accelerates electromigration, dielectric breakdown, and material fatigue, which collectively contribute to premature burnout of the certain temperature-sensitive components. For instance, the electrolytic capacitors generate very little heat when compared with other components of the power electronic system, but are affected by the heat generated by heat-generating components. As a result, the electrolytic capacitors are known to have reduced life expectancy when exposed to high temperatures, even if the overall system is within rated thermal limits.

FIG. 1 illustrates a simplified schematic of the Power electronic system, in accordance with the prior art. As can be seen from the schematic of the Power electronic system 100, a electrolytic capacitor EC1 is connected between Stage 1 circuit comprising an Inductor (L1), a Diode (D2), a MOSFET (Q1), and Stage 2 circuit comprising a Inductor (L2), a Diode (D5), MOSFET (Q2). Further, a physical layout of the Power electronic system is typically arranged to align with the schematic layout in order to reduce lead length, and electromagnetic interference (EMI), and ensure that EC1 is positioned between Stage 1 and Stage 2. As a result, EC1 is positioned in a way that places it among all the heat-generating components. The same is true for an electrolytic capacitor EC3. As the EC1 and EC3 are near to the heat-generating components, the electrolytic capacitors may get affected. Further, the electrolytic capacitor of large value and large size are required to “Valley Fill” AC input waveforms or to smooth out the output of switching mode.

According to some prior art, a heat sink is provided around the components of the Power electronic system 100 in order to dissipate the heat generated during the operation by the heat-generating component. Further, an enclosure of the Power electronic system is generally made of a high thermally conductive material like aluminium, due to which the process of heat dissipation from the Power electronic system gets hinder. Furthermore, an enclosure and the heat sink are often being the same part of the Power electronic system 100.

Efforts have been made to address these thermal management challenges associated with the power electronic system, but the same has not been successful. Conventionally, the power electronic system relies on simple heat sinks or basic convection cooling, which are often inadequate for effectively dissipating the heat generated. Such conventional methods fail to provide sufficient cooling, leading to overheating and subsequent performance degradation of the power electronic system. Additionally, some designs attempt to use more complex and expensive cooling solutions, such as liquid cooling or advanced thermal materials, but these approaches are not cost-effective for widespread application and can introduce additional points of failure.

Moreover, attempts have been made to direct airflow to specific areas of the power electronic system, either naturally or through forced convection. However, these were also inadequate due to the conductive properties of the enclosure, which equalize temperatures across different areas. The net effect was that even with directed airflow, the entire enclosure, including areas meant to be cooler, still reached similar temperatures.

To overcome the above-mentioned challenges associated with conventional power electronic system, there is a need for efficient thermal management by thermally isolating the thermally sensitive components in the power electronic system through both conduction and convection isolation. Such that life of the temperature-sensitive components can be prolonged, that further results in improving system reliability.

### SUMMARY

The summary is provided to introduce aspects related to lighting systems and efficient thermal management of the lighting systems, and the aspects are further described below in the detailed description. This summary is not intended to identify essential features of the claimed subject matter nor is it intended for use in determining or limiting the scope of the claimed subject matter.

An object of the present disclosure is to provide intentional non-alignment of physical component layout with electrical signal flow, a direct departure from conventional design practice that achieves superior thermal isolation for lifespan-critical components.

A further object of the present disclosure is to provide a power electronic system with a separate area or region defined based on temperature characteristics, such that thermal-sensitive components are spatially arranged or thermally isolated to minimize exposure to excessive heat. Such a configuration aims to reduce thermal stress on critical components (like an electrolytic capacitor) and thereby improve the overall operational lifespan and reliability of the power electronic system.

Another object of the present disclosure is to mitigate thermal interaction between thermal-sensitive components and other components in the power electronic system, thereby facilitating improved heat dissipation, reduced energy consumption.

Another object of the present disclosure is to provide he power electronic system with improved efficiency, reliability, and performance.

Another object of the present disclosure is to facilitate enhanced thermal management to enable development of more compact and versatile power electronic systems suitable for a wide range of applications.

In an embodiment, the present disclosure discloses the power electronic system. The power electronic system comprises at least one enclosure enclosing at least a first area and a second area, wherein the first area has a lower temperature than the second area. The power electronic system further comprises the first area comprising a first set of electronic components, and the second area comprising a second set of electronic components and a third set of electronic components. The second set of electronic components receives electrical power from a power source and provides output to the first set of electronic components. On the other hand, the third set of electronic components receives the input from the first set of electronic components and provides the output to a load. Further, the first set of electronic components comprises at least one thermal-sensitive component that is more temperature-sensitive than either of the second set of electronic components and the third set of electronic components. Furthermore, the first area is thermally isolated from the second area.

In another embodiment, the present disclosure discloses that the first area does not overlap with the second area.

In another embodiment, the present disclosure discloses that a temperature of the first area is at least 5 degrees Celsius lower than the second area.

In another embodiment, the present disclosure discloses that the first set of electronic components comprises at least one electrolytic capacitor.

In another embodiment, the present disclosure discloses that the power electronic system may comprise any one of an LED driver, a solar inverter, an AC-AC power converter, an AC-DC power converter, a DC-to-DC power converter, a DC-to-AC power converter, or a power amplifier.

In another embodiment, the present disclosure discloses that the at least one enclosure comprises a first enclosure and a second enclosure, the first enclosure enclosing the first area and the second enclosure enclosing the second area.

In another embodiment, the present disclosure discloses that the first enclosure is thermally isolated from the second enclosure by using at least one process of conduction and convection.

In another embodiment, the present disclosure discloses that the second set of electronic components and the third set of electronic components generate a majority of heat in the power electronic system.

In another embodiment, the present disclosure discloses that the first set of electronic components generates less than 10% of a total heat generated by the power electronic system

In another embodiment, the present disclosure discloses that the first enclosure receives a first airflow, and the second enclosure receives a second airflow.

In another embodiment, the present disclosure discloses that a source of the first airflow is different from a source of the second airflow.

In another embodiment, the present disclosure discloses that the first enclosure receives the first airflow, and the second enclosure receives the second airflow along a part of the first airflow that is received via the first enclosure, based on a positional placement of the first enclosure corresponding to the second enclosure, wherein the first enclosure comprises the first set of electronic components and the second enclosure comprises the second set of electronic components and the third set of electronic components.

In another embodiment, the present disclosure discloses that the positional placement comprises vertical positional placement, horizontal positional placement, and diagonal positional placement.

In another embodiment, the present disclosure discloses that the second set of electronic components comprise an input stage of a Switch-Mode Power Supply (SMPS), the third set of electronic components comprise an output stage providing the SMPS as the output to the load, and the first set of electronic components comprise components at the center stage electrically between the second set of electronic components and the third set of electronic components. Further, the first set of electronic components comprises at least one electrolytic capacitor.

Other aspects and advantages of the present disclosure will become apparent from the following description, taken in conjunction with the accompanying drawings, illustrating by way of example, the principles of the present disclosure.

### BRIEF DESCRIPTION OF DRAWINGS

Non-limiting and non-exhaustive embodiments of the disclosure are described with reference to the following figures, wherein reference numerals refer to like parts throughout the various views unless otherwise specified. The accompanying drawings constitute a part of the description and are used to provide a further understanding of the present disclosure. Such accompanying drawings illustrate the embodiments of the present disclosure used to describe the principles of the present disclosure. The embodiments are illustrated by way of example and not by way of limitation in the figures of the accompanying drawings in which references indicate similar elements. It should be noted that references to “an” or “one” embodiment in this disclosure are not necessarily to the same embodiment, and they mean at least one. In the drawings:

FIG. 1 illustrates a simplified schematic of a power electronic system, in accordance with the prior art;

FIG. 2 illustrates a block diagram illustrating a power electronic system, in accordance with an embodiment of the present disclosure;

FIG. 3A through FIG. 31 illustrates a block diagram depicting various configurations and arrangements of heat sink of the power electronic system, in accordance with an embodiment of the present disclosure;

FIG. 4A illustrates a 3D view of the power electronic system with electrolytic capacitors positioned away from heat-generating components, in accordance with an embodiment of the present disclosure;

FIG. 4B illustrates an example schematic diagram for the power electronic system, according to an embodiment of the present disclosure;

FIG. 4C illustrates another example schematic diagram for the power electronic system, according to an embodiment of the present disclosure;

FIG. 5 illustrates a 3D view of the power electronic system with electrolytic capacitors positioned along with the heat-generating components, according to the conventional art;

FIGS. 6A and 6B illustrate an example of a comparison results of thermal analysis depicting the impact of heat generated on the electrolytic capacitors positioned away from the heat-generating components of the electronic system as compared to conventional art;

FIGS. 7(A)-7(E) is an exemplary illustration of a 3D view of various positions of the LED driver assembly within the enclosure, in accordance with an embodiment of the present disclosure;

FIG. 8(A) through FIG. 8(F) illustrates a 3D view of different configurations of the power electronic system positioned within the enclosure, in accordance with an embodiment of the present disclosure;

FIG. 9 illustrates a 3D view of a wrap round heat sink, according to an embodiment of the present disclosure;

FIG. 10 illustrates a cross-sectional view of the Power electronic system with a wrap around heat sink, according to an embodiment of the present disclosure;

FIG. 11 illustrates a 3D view of the Power electronic system with a heat sink associated with inductors and transformers, according to an embodiment of the present disclosure;

FIG. 12 illustrates a cross-sectional view of the power electronic system with a heat sink associated with inductors and transformers, according to an embodiment of the present disclosure;

FIG. 13 illustrates a 3D view of the power electronic system with a gap created in potting to provide a degree of thermal conduction, in accordance with an embodiment of the present disclosure;

FIG. 14 illustrates a 3D view of the power electronic system with a plastic cap encapsulating the first area, according to an embodiment of the present disclosure;

FIGS. 15A and 15B illustrate a thermal analysis of the power electronic system with a plastic cap in a case of vertical and horizontal orientation of the power electronic system relative to the enclosure respectively, according to an embodiment of the present disclosure;

FIG. 16 illustrates a 3D view of a foam disposed in the gap of the power electronic system, according to an embodiment of the present disclosure;

FIG. 17 illustrates a 3D view of a power electronic system encapsulated with a metal isolated cap, according to an embodiment of the present disclosure;

FIG. 18 illustrates a 3D view of a foam and a spacer disposed in the gap of the power electronic system, according to an embodiment of the present disclosure;

FIG. 19A and FIG. 19B illustrates a 3D view of a power electronic system, in accordance with an embodiment of the present disclosure;

FIG. 20 illustrates an exemplary 3D view depicting design and installation of various components of the power electronic system assembly in an LED lighting system, in accordance with an embodiment of the present disclosure;

FIG. 21 illustrates an exemplary 3D view depicting the design and installation of various components of the power electronic system assembly in a linear high bay lighting system, in accordance with an embodiment of the present disclosure;

FIG. 22 illustrates an exemplary 3D view depicting the design and installation of various components of the power electronic system assembly in an LED-based canopy setup, in accordance with an embodiment of the present disclosure;

FIG. 23 illustrates an example of a layout depicting locations of key components of the power electronic system, in accordance with an embodiment of the present disclosure;

FIG. 24 illustrates an exploded view of the power electronic system assembly including a thermal management mechanism, in accordance with an embodiment of the present disclosure; and

FIG. 25 through FIG. 30 illustrate sequential steps of forming the power electronic system assembly including the thermal management mechanism, in accordance with an embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” or “lateral” or “adjacent” or “diagonal” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Unless otherwise expressly stated, comparative, quantitative terms such as “less than” and “greater than”, are intended to encompass the concept of equality. As an example, “less” can mean not only “less” in the strictest mathematical sense, but also, “less than or equal to.”

The terms/phrases “power electronic system” and “system” may be used interchangeably throughout the description.

The terms/phrases like “temperature-sensitive” and “thermal-sensitive” may be used interchangeably throughout the description.

The present disclosure relates to the power electronic system configured with spatial separation of components based on thermal characteristics, with the objective of enhancing the operational life and reliability of the the power electronic system. In particular, the the power electronic system includes at least two distinct areas, wherein thermal-sensitive components are positioned in a first area that maintains a lower thermal profile relative to a second area containing higher heat-generating components. By managing the internal temperature distribution within the power electronic system and minimizing thermal stress on vulnerable components, the present invention seeks to reduce the likelihood of premature failure and degradation commonly associated with prolonged exposure to elevated temperatures in the power electronic system.

The power electronic system described herein may be implemented in various forms depending on the application and functional requirements. In one or more embodiments, the power electronic system may comprise any one of: an LED driver configured to regulate current for solid-state lighting; a solar inverter used to convert DC power from photovoltaic panels into AC power; an AC-to-AC power converter for frequency or voltage modulation; an AC-to-DC power converter such as a rectifier for supplying DC loads; a DC-to-DC power converter used to step up or step down voltage levels in DC systems; a DC-to-AC power converter such as an inverter for driving AC loads from a DC source; or a power amplifier for signal amplification in audio, radio frequency (RF), or industrial applications. The thermal management and spatial configuration principles disclosed herein may be applied to any of these systems to improve performance and extend operational lifespan.

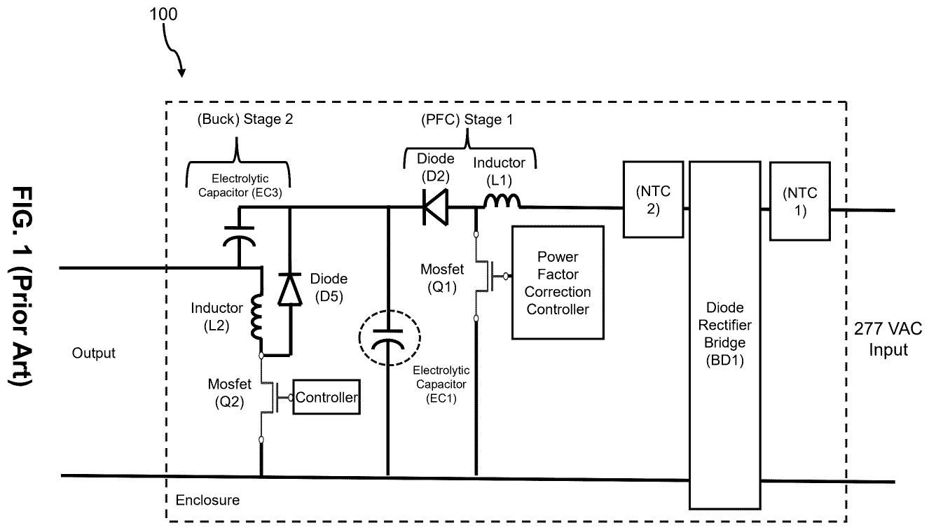

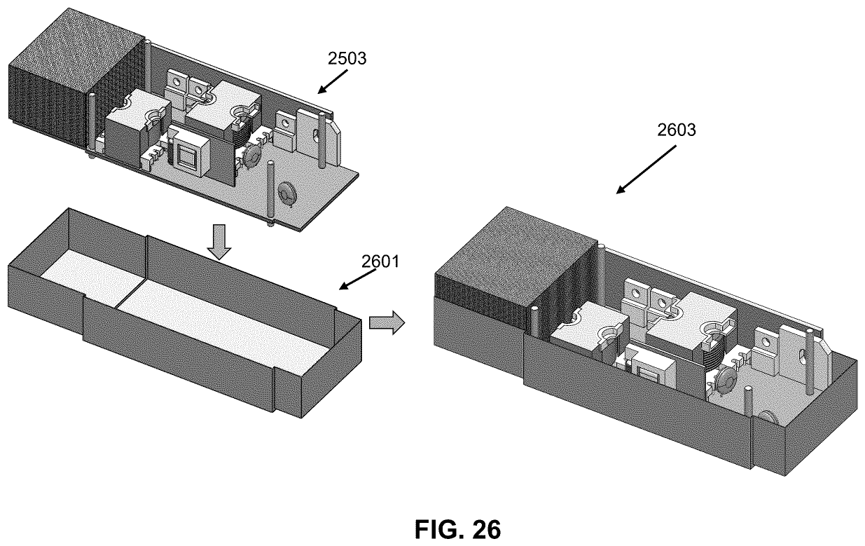

The present disclosure offers a unique power electronic system that effectively addresses the issues of the prior arts, and provides a solution that combines efficiency, affordability, and extended lifespan. Embodiments of the present disclosure will be described hereinafter with reference to FIG. 1 through FIG. 30.

As an example, when the power electronic system is implemented as the LED driver The LED driver powers LED by transforming electrical input to an electrical output suitable for the LED. The LED driver may include a driver box, a driver housing, and electronic components such as PCBs, transistors, electrolytic capacitors, resistors, transformers, and inductors. The electrolytic capacitors in the LED driver generates less heat than the other components of the LED driver but is more temperature-sensitive than the other components of the LED driver. Considering an example of a 150 Watt (W) high bay LED luminaire, a heat of 60.5 W is generated from the LED and 8.66 W from the driver electronics. Further, for 100,000 hours of reliability of the lighting system, the allowable temperature for the LED is approximately 105° C. and 65° C. for the driver. If an ambient temperature of TA=50° C., then dT (Delta in temperature) required for 100,000 hours reliability is approximately 55° C. for the LED and 15° C. for the LED driver. Thus, the temperature of the LED can increase by 50° C., but the temperature of the LED driver can only increase by 15° C. Therefore, if the temperature-sensitive component like the electrolytic capacitors are subjected to more heat than 15° C., then lifespan of the electrolytic capacitors may be shorten. This in turn shorten the life of the LED driver. Thus, the LED driver's reliability is significantly based on the temperature-sensitive component like the electrolytic capacitors than the other heat-generating components.

In the example, for improving the life of the LED driver, the area of the LED driver may be segregated into two different areas which may be known as the first area and the second area. In the LED driver, a first airflow blows in the first area, a second airflow blows in the second area, and an enclosure of the LED driver. The first airflow dissipates heat from the first area of the LED driver comprising the thermal-sensitive components whereas the second airflow dissipates the heat from the second area of the LED driver comprising the heat-generating components. The first airflow and the second airflow are physically separated from one another to reduce thermal convection coupling between the two airflows. A detailed explanation of components and placement will be described in the forthcoming paragraphs. Further, the labels to similar parts/area/components are kept the same throughout the disclosure for ease of understanding.

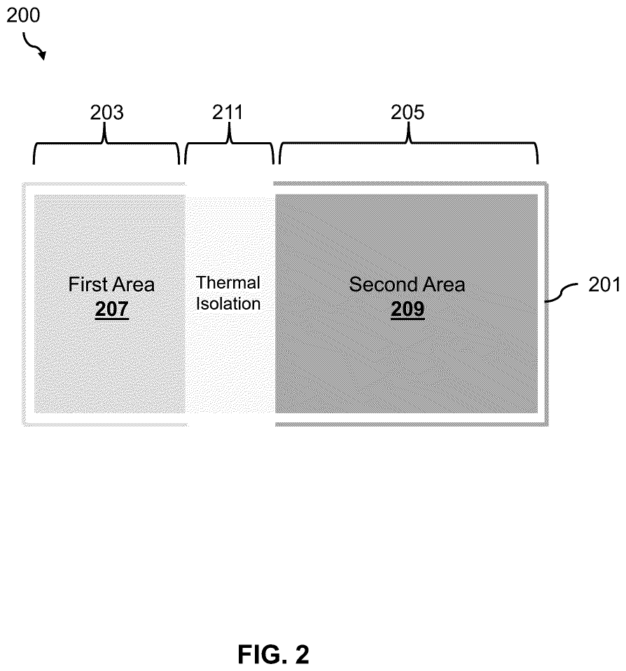

FIG. 2 illustrates a block diagram illustrating a power electronic system, in accordance with an embodiment of the present disclosure.

In an embodiment, the power electronic system 200 comprises an enclosure 201 having a first portion 203 and a second portion 205. In an embodiment, the first area 207 is disposed within the first portion 203 and the second area 209 is disposed within the second portion 205. Further a thermal isolation 211 is provided between the first area 207 and the second area 209 by separating the first area 207 from the second area 209 thereby restricting conduction through the enclosure 201 and both thermal conduction and convection within the enclosure 201.

In an embodiment, the first area 207 houses a first set of electronic components, whereas the second area 209 houses a second set of electronic components and a third set of electronic components. The first area 207 and the second area 209 are thermally isolated by separating the first area 207 and the second area 209 through various means like plastic insulation, foam, potting gap in the enclosure 201, or by providing wrap round heat sinks. In an embodiment, the first set of electronic components includes thermal-sensitive component that is more temperature-sensitive than either of the second set of electronic components and the third set of electronic components. The second set of electronic components and the third set of electronic components include components that generate more heat than the first set of electronic components. In a non-limiting example, the first set of electronic components may include the electrolytic capacitors and the second set of electronic components may include MOSFET, inductors, transformers, diodes, and the like.

During the operation of the power electronic system, the first area is maintained at a temperature lower than the temperature of the second area by at least 5° C. The temperature difference between the first area and the second area may be determined based on various thermal metrics, depending on system design and application requirements. In one example, the temperature of first area may be measured as an average operating temperature, calculated by sampling temperature values at multiple locations within each area using embedded sensors, thermocouples, or infrared thermography. Alternatively, the peak temperature presenting the highest recorded temperature within the first area and the second area respectively. The peak temperature may be used for identifying temperature difference between the first area and the second area. In another embodiment, the steady-state temperature may be used for identifying temperature difference between the first area and the second area, where the temperature for the respective area may be evaluated. The steady-state temperature may be obtained after the power electronic system has been operating under constant load conditions for a predefined period, such that transient thermal fluctuations have subsided. Another alternative, like the time-averaged temperature over a complete operational cycle (e.g., a dimming cycle in an LED driver) may be used to capture dynamic heating behavior in the first area and the second area. In certain cases, the temperature comparison may also be based on the surface temperature of representative components within each area, such as comparing the electrolytic capacitor in the first area with a switching transistor in the second area. In each of the aforementioned methodology, the temperature of the first area is considered to be at least 5° C. lower than that of the second area when the corresponding measured values, based on the chosen methodology.

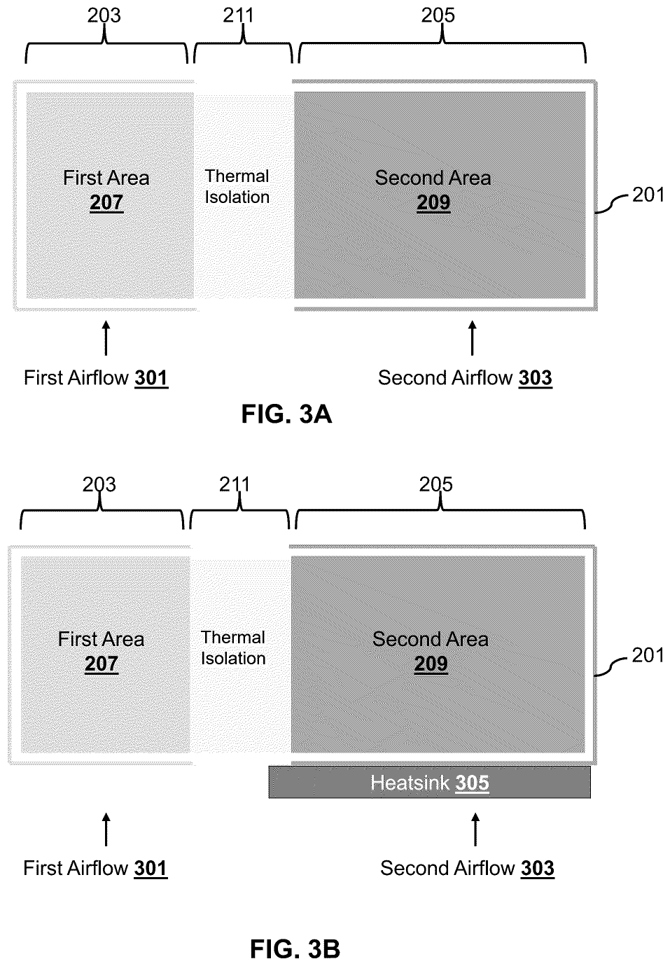

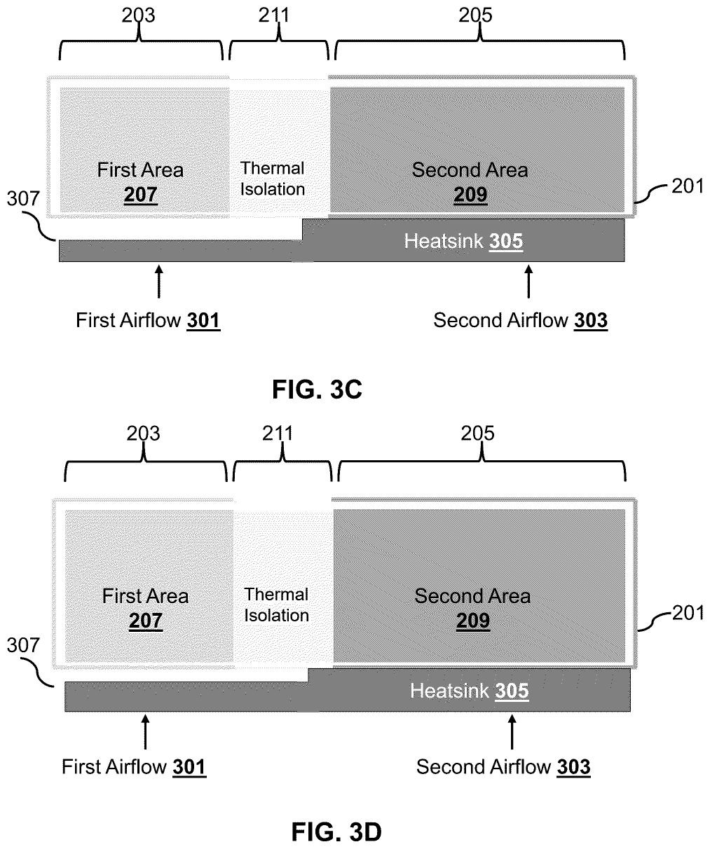

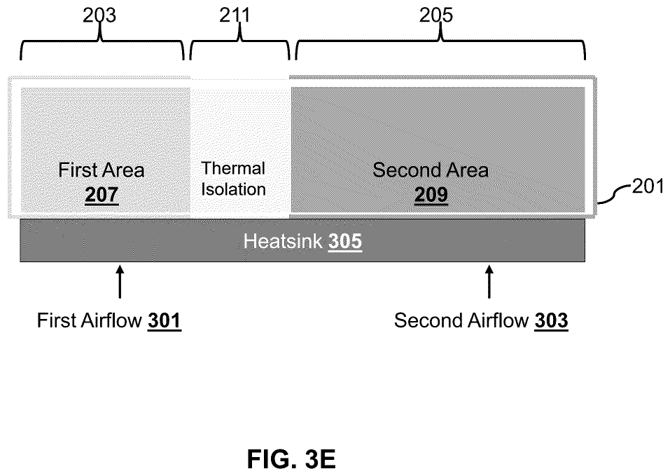

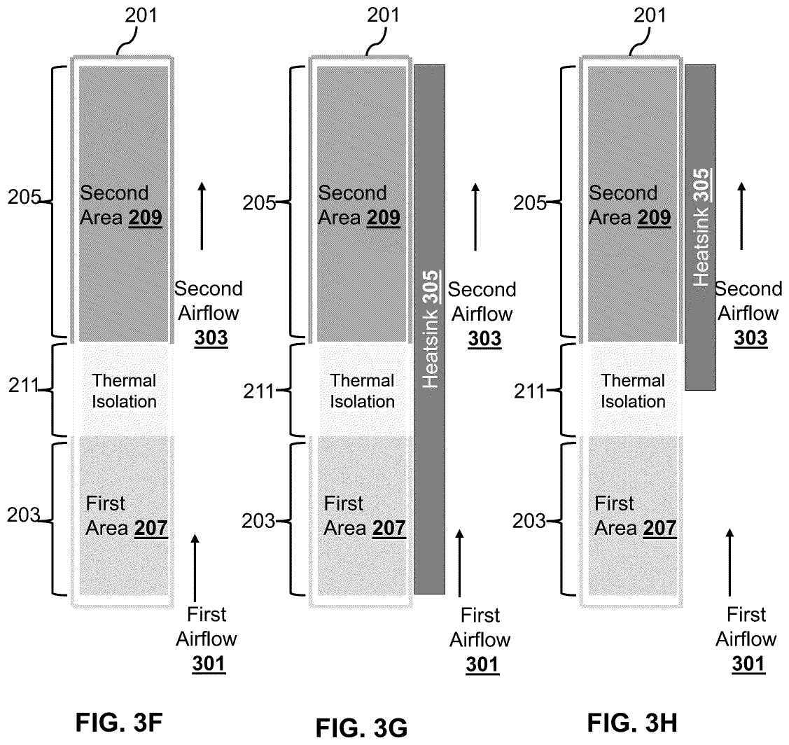

FIG. 3(A) through FIG. 3(B) illustrates a block diagram depicting various configurations and arrangements of the heat sink of the power electronic system, in accordance with an embodiment of the present disclosure.

Referring to FIG. 3A, according to the example configuration, the power electronic system 200 includes no heat sink. According to an example embodiment, the thermal isolation is provided between the first area 207 and the second area 209 by the separating each other. Further, according to an example embodiment, the enclosure 201 can be cooled using external methods such as conduction, convection, or radiation. The convection can further be categorized as natural convection or forced air convection.

According to an example embodiment, a first air flow 301 directed to the first area 207 and the second air flow 303 directed to the second area 209 is provided so that during the operation, the air, at first, flows via the first airflow 303 of the first area 207 then the air flows via the second airflow 305 of the second area 209 so that the first set of components receives cooler air than the second set of components. Accordingly, the first area 207 is maintained at a temperature that is lower than a temperature of the second area 209 for maintaining a degree of thermal isolation between each other. Thus, the first airflow 301 maintains the one or more electrolytic capacitors at a first temperature and the second airflow 303 maintains the second set of components and the third set of components of the second area 209 at a second temperature which may be equal or higher than the first temperature. Thereby making the temperature in the first area 207 cooler than the second area 209.

FIGS. 3B to 31 illustrate various configurations in which the heat sink is adjacent to and coupled to the second area 209. As illustrated in these example configurations, the heat sink is integrated with the power electronic system 200, as disclosed in FIG. 2, in various arrangements.

Referring to FIG. 3B, according to the example configuration, the heat sink 305 is adjacent to and coupled to the second area 209. Referring to FIG. 3C and FIG. 3D, the heat sink 305 is extended to the first area 207 where a gap 307 is maintained between the first area 207 and the second area 209. According to an example embodiment of FIG. 3C, the gap 307 between the first area 207 and the heat sink 305 is more than the gap 307 as shown in FIG. 3(D). Thus, the configuration as shown in FIG. 3C, hinders the heat dissipation in the thermally sensitive components.

Referring to FIG. 3(E), according to an example embodiment, the heat sink 305 is thermally coupled to the first area 207 and the second area 209. Referring to FIGS. 3(F) to 3(H), according to the example embodiment, the electronic system 200 is positioned in a vertical orientation. According to the example embodiment, as the air flows from the first area 207 to the second area 209, the hot air goes up while making the lower area i.e. the first area 207 cooler than the upper area i.e. the second area 209. Thus, the temperature in the first area 207 is maintains a lower temperature than the second area 209.

Referring to FIG. 3(I), according to the example embodiment, the heat sink 305 is thermally coupled with the first area 207 and the second area 209 separately. As can be seen from the above-explained configurations the second heat sink is configured to be attached in the orientation including one of top, bottom, or side positions relative to the enclosure 201.

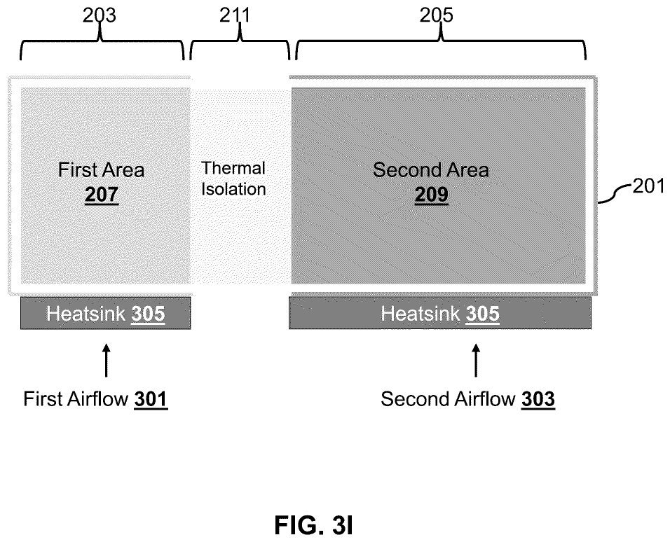

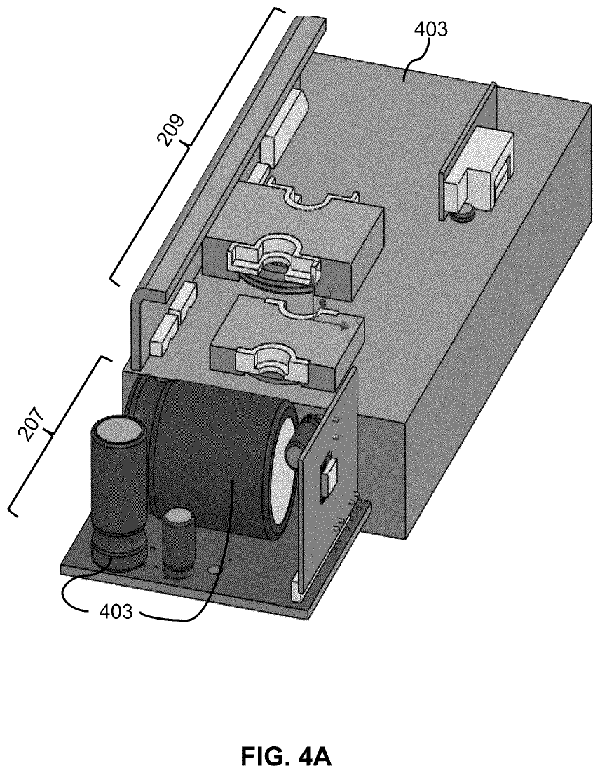

FIG. 4A illustrates a 3D view of the power electronic system with the electrolytic capacitors positioned away from the heat-generating components, in accordance with an embodiment of the present disclosure. According to an embodiment, in order to reduce conduction and convection, a spatial separation is provided between the first area 207 and the second area 209 internally to the enclosure 201. According to an embodiment, the electrolytic capacitors 401 are positioned away from the heat-generating components 403 of the power electronic system 200. In particular, the electrolytic capacitors 401 are disposed in the first area 207 and the heat-generating components 403 are disposed in the second area 209. Accordingly, the spatial separation is sufficient to maintain a temperature difference between the two areas.

FIG. 4B illustrates an example schematic diagram for the power electronic system, according to an embodiment of the present disclosure. According to an embodiment, the power electronic system comprises at least one enclosure enclosing at least the first area 207 and the second area 209, wherein the first area 207 has a lower temperature than the second area 209. The electrolytic capacitors EC1 and EC3 are positioned away from the heat-generating components provided in the second area 209. According to the example embodiment, the electrolytic capacitors EC1 and EC3 are included in the first area 207 and the heat-generating components are included in the second area 209. The heat-generating components comprise the second set of electronic components 405 and a third set of electronic components 409. The second set of electronic components 407 receives electrical power from a power source (like 277 VAC input), and provides output to the first set of electronic components 405. Further the third set of electronic components 409 receives the input from the first set of electronic components 405 and provides the output to a load (may also considered as a power output). Furthermore, the first set of electronic components 405 comprises at least one thermal-sensitive component (like EC1 and EC3) that is more temperature-sensitive than either of the second set of electronic components 407 and the third set of electronic components 409. The first area 207 is thermally isolated from the second area 209.

The first area 207 contains components which are thermally sensitive, such as the electrolytic capacitors (EC1 and EC3). For instance, at least one component needs to be maintained at a temperature below <70° C., 80° C., 90° C. When these components are combined, they generate a small portion of the overall heat power (<10%, <20%, <30%) when compared with the total heat generated by the power electronic system. Further, the second area 209 contains components that are less thermally sensitive, such as transformers, MOSFETS, Diodes, and Bridges, and can be operated at higher temperatures, such as >70° C., 80° C., 90° C. When these components are combined, they contribute to the majority of the overall heat power (>70%, >80%, >90%) when compared with the total heat generated by the power electronic system.

In an embodiment, the present disclosure discloses that the first area 207 does not overlap with the second area 209.

In an embodiment, the present disclosure discloses that the at least one enclosure may comprises a first enclosure and a second enclosure, the first enclosure enclosing the first area 207 and the second enclosure enclosing the second area 209.

In an embodiment, the present disclosure discloses that the first enclosure receives a first airflow, and the second enclosure receives a second airflow. Further, a source of the first airflow may be different from a source of the second airflow. Further, the first enclosure receives the first airflow, and the second enclosure receives the second airflow along a part of the first airflow that is received via the first enclosure, based on a positional placement of the first enclosure corresponding to the second enclosure, wherein the first enclosure comprises the first set of electronic components 405 and the second enclosure comprises the second set of electronic components 407 and the third set of electronic components 409. Furthermore, the positional placement comprises vertical positional placement, horizontal positional placement, and diagonal positional placement.

In another embodiment, the present disclosure discloses that the first enclosure may be thermally isolated from the second enclosure by using at least one process of conduction and convection.

In an embodiment, the present disclosure discloses that the second set of electronic components 407 comprise an input stage of a Switch-Mode Power Supply SMPS, the third set of electronic components 409 comprises an output stage providing the SMPS as the output to the load, and the first set electronic components 405 comprise components at the center stage electrically between the second set of electronic components 407 and the third set of electronic components 409.

FIG. 4C illustrates another example schematic diagram for the power electronic system, according to an embodiment of the present disclosure. According to some embodiment, a film capacitors (PF1) is placed physically closer to the middle of the second area 209 and in between the second set of electronic components 407 and the third set of electronic components 409. The PF1 provides damp high frequencies and to minimize EMI, the PF1 is implemented. The film capacitors can typically withstand high temperature and may be kept within the second area 209. According to some embodiment, another film capacitor (PF2) may be placed near EC1 for a similar purpose to PF1. The film capacitor has lower capacitance than electrolytic capacitors and therefore cannot replace electrolytic capacitors. Since the film capacitors do not generate much heat and are not temperature sensitive components, therefore the disclosed designed is unaffected by its implementation.

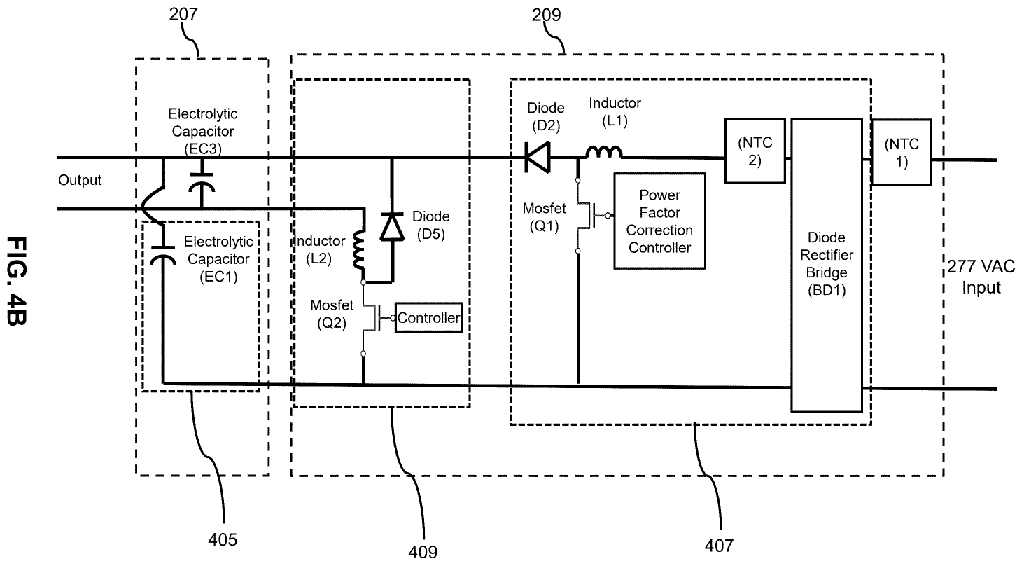

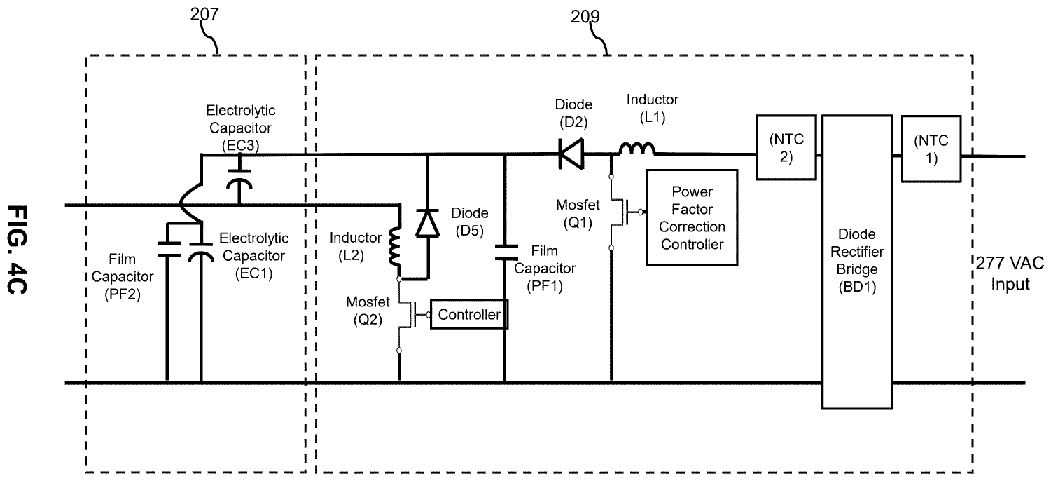

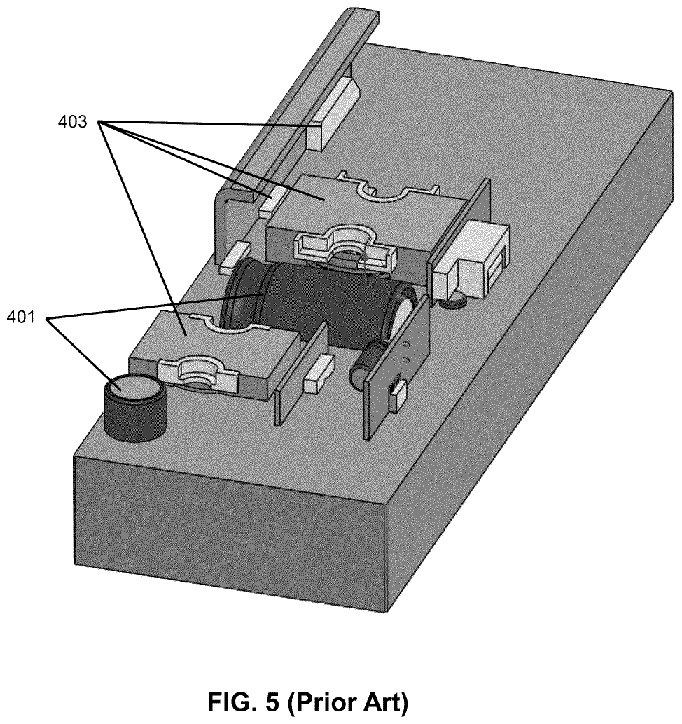

FIG. 5 illustrates a 3D view of the power electronic system with the electrolytic capacitors positioned along with the heat-generating components, according to the conventional art. As can be seen, the electrolytic capacitors 401 are buried between all the heat-generating components 403 between stage 1 (input stage) and stage 2 (output stage) in order to keep the wiring between components short. Further, the physical layout generally follows the schematic order as depicted in FIG. 1. Typically, the temperature-sensitive components i.e. the electrolytic capacitors 401 collectively generate approximately 7.7% of the total heat within the system. These components may have a temperature limit of 80° C. for a lifetime of 100,000 hours, with a reduction in lifetime by a factor of 2 times for every 10° C. increase in the temperature. Taking an assumed ambient air temperature (TA) of 60° C. into consideration, these components are designed to only increase in temperature by 20° C. Further, less temperature-sensitive components (i.e. the second set of electronic components 407 and the third set of electronic components 409) 403 may contribute to around 92.3% of the total heat. The components with the lowest temperature limit are restricted to 110° C. for a lifetime of 100,000 hours. Accounting for the assumed ambient air temperature of 60° C., these components can increase in temperature by 50° C., which is 2.5 times higher than the temperature rise allowed for the temperature-sensitive components. When all components are considered together in terms of thermal management, the presence of temperature-sensitive components imposes a limit on the temperature rise to 20° C., which is 3 times lower than the 60° C. rise allowed for the less temperature-sensitive components 403.

Accordingly, by strategically separating the components based on their thermal characteristics, and keeping the more temperature-sensitive components away from the less temperature-sensitive components, the less temperature-sensitive components can operate at higher temperatures, the overall system performance can be significantly enhanced. According to the disclosed configuration as depicted in FIGS. 4A and 4B, positioning the thermally sensitive components spatially away from the heat-generating component aids in maintaining a required temperature difference and thermal stability.

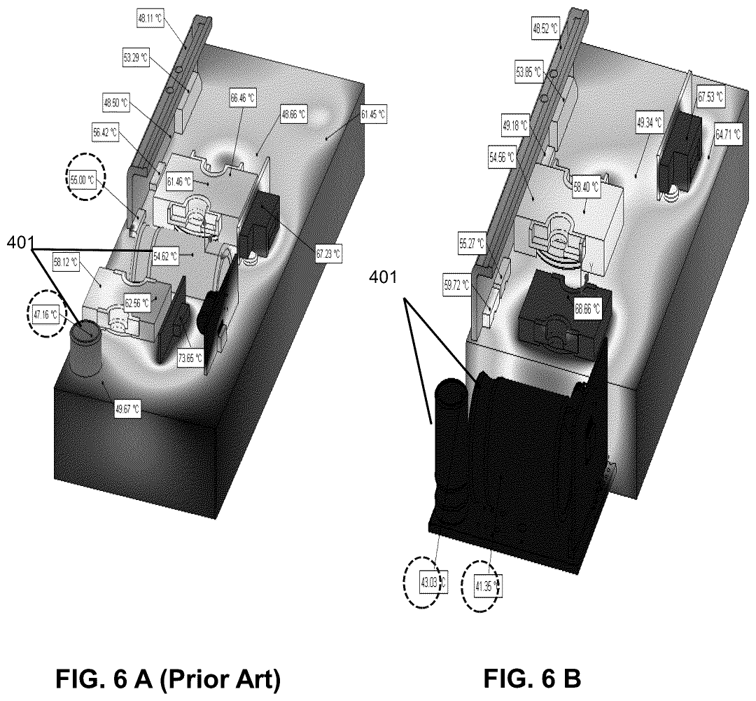

FIGS. 6A and 6B illustrate an example of a comparison results of thermal analysis depicting the impact of heat generated on the electrolytic capacitors positioned away from the heat-generating components of the electronic system as compared to conventional art. As evident from FIG. 6B, due to the positioning of the electrolytic capacitors 401 away from the heat-generating components 403, the temperature of the electrolytic capacitors 401 is maintained at 43.03° C. and 41.35° C. as compared to the conventional art where the temperature of the electrolytic capacitors 401 is maintained at 47.16° C. and 55.00° C. Thus, the spatial separation aids in maintaining the temperature of the first set of electronic components cooler than the second set of electronic components and the third set of electronic components.

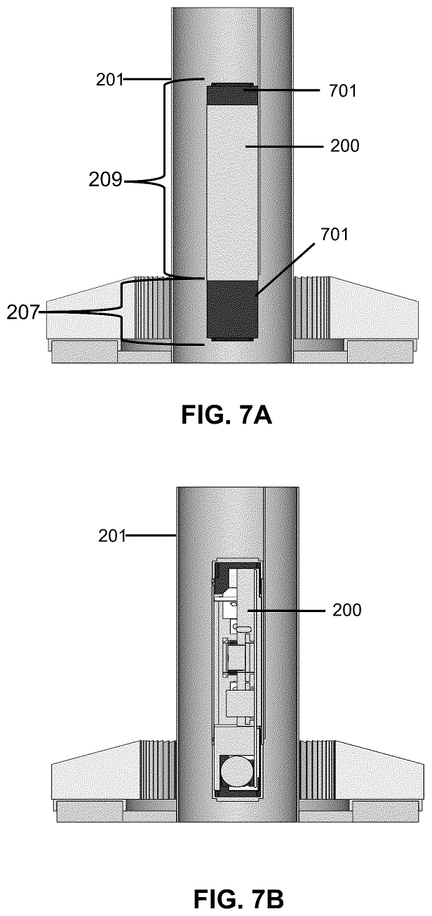

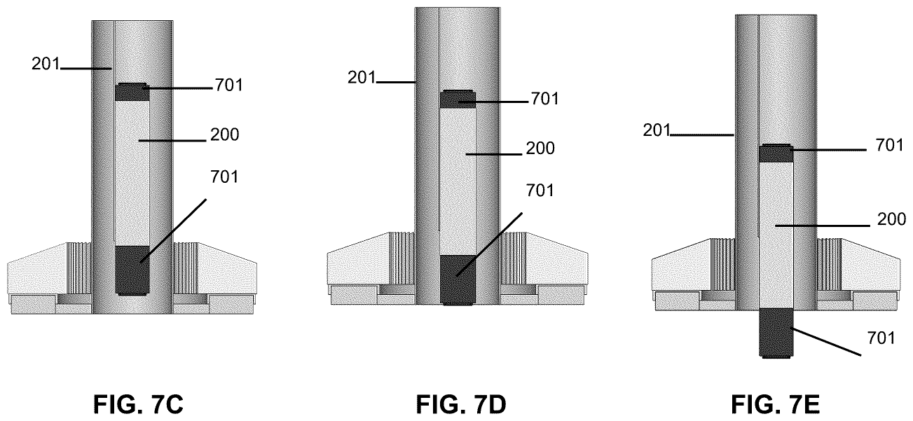

FIGS. 7(A)-7(E) is an exemplary illustration of a 3D view of various positions of the LED driver (power electronic system) assembly within the enclosure, in accordance with an embodiment of the present disclosure. According to an embodiment of the present disclosure, a plastic cap 701 is provided which is in contact with the heat sink 305 of the first area 207. The plastic cap 701 encases the first area 207 on three sides such that the thermal isolation is provided between the first area 207 and the second area 209 on a fourth side. In an embodiment, the plastic cap includes a clearance on all sides to prevent interference with an attachment of a central aluminum extrusion to a mounting surface, and the clearance may be approximately 0.5 mm.

Referring to FIGS. 7(A)-7(D), according to the example embodiments, the LED driver (power electronic system 200) is positioned within the enclosure 201. According to some embodiment, the first area 207 encasing the plastic cap 701 is out of the enclosure as depicted in FIG. 7E.

Referring to FIGS. 7(A)-7(E), the LED driver (power electronic system 200) assembly is encased at its two ends by the plastic cap 701. In an embodiment, one of the ends of the LED driver corresponding to the first area 207 is covered with the plastic cap 701 of a longer size. Further, the other end of the LED driver corresponding to the second area 209 is covered with the plastic cap 701 of a shorter size. Thus, the long end plastic cap 701 is disposed of in the first area 207 of the LED driver, while the short end plastic cap is disposed in the second area 207.

The LED driver (power electronic system 200) assembly mounted at different positions within the enclosure 201. offer significant benefits by reducing heat exposure to the electrolytic capacitors 401 during operation, thereby extending the lifespan of the LED driver and in turn LED luminaire. Most importantly, the strategic placement of the LED driver relative to the LEDs and the positioning of the electrolytic capacitor 401 at the near end of the LEDs, yet away from the heat-generating components, creates a unique component configuration that further extends the lifespan of the LED driver.

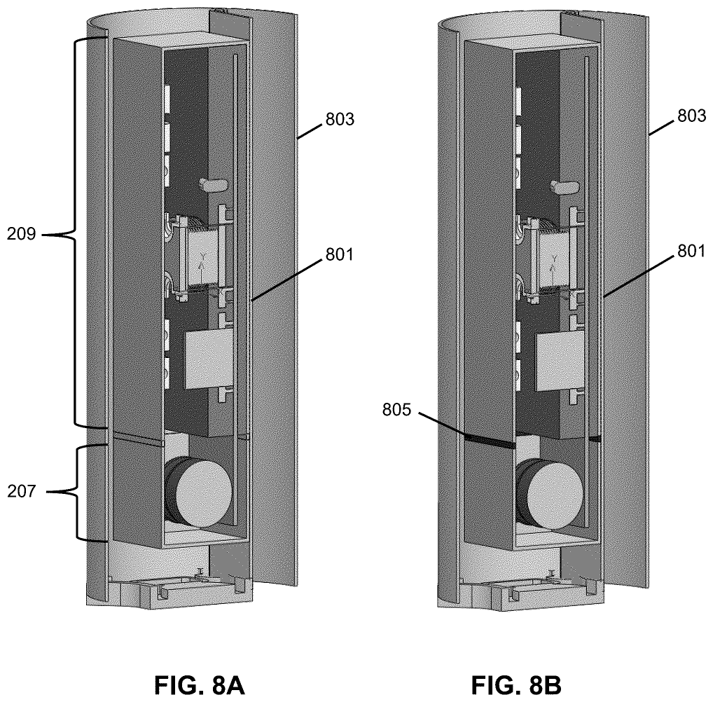

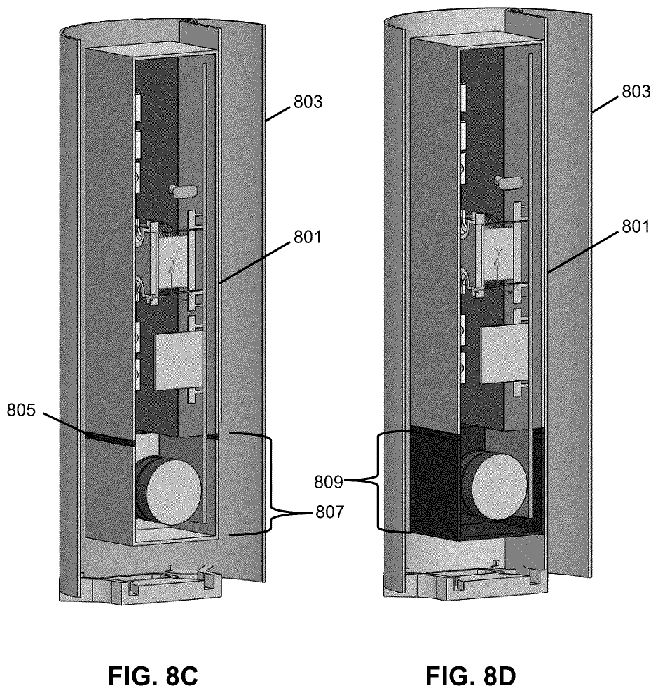

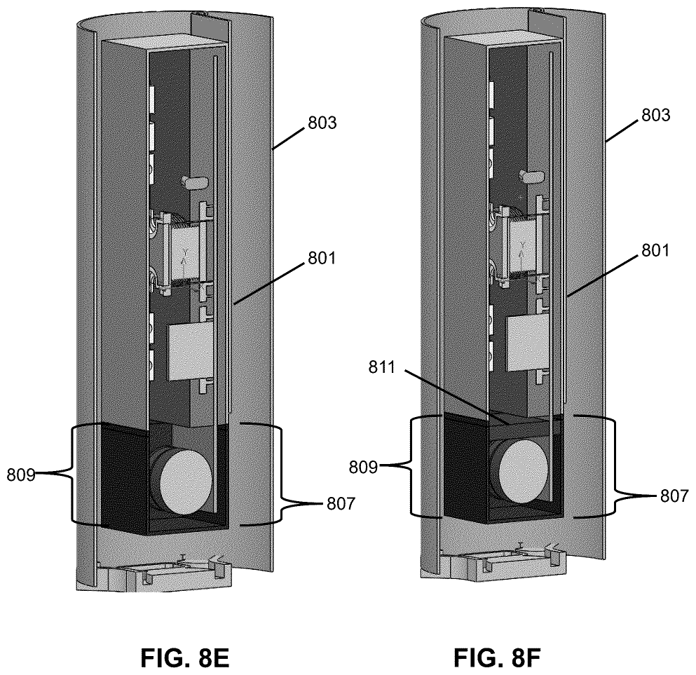

FIG. 8A through FIG. 8F illustrates a 3D view of different configurations of the power electronic system positioned within the enclosure, in accordance with an embodiment of the present disclosure. Referring to FIG. 8A, the heat sink is thermally coupled to each of the first area 207 and the second area 209 of the power electronic system 200 assembly. The heat sink 801 is configured to be attached in an orientation relative to the enclosure 803.

Referring to FIG. 8B, the heat sink 801 is thermally coupled to each of the first area 207 and the second area 209 of the power electronic system 200 assembly. The heat sink 801 is configured to be attached in an orientation relative to the enclosure 803. Further, as shown in FIG. 8B, the plastic insulation 805 is provided for the thermal isolation to substantially separates the enclosure 803 into two portions such that the heat generated by the electronic components in the second area 209 does not affect the electronic components of the first area 207. Thus, the second example configuration of the power electronic system 200 assembly as shown in example FIG. 8B helps in managing the thermal heat generated by the second set of electronic components and the third set of electronic components in the second area. The first set of electronic components are thermally isolated from the second set of electronic components and the third set of electronic components using at least one process among conduction and convection. The reference of the first area 207 and the second area 209 can be referred to through FIG. 8A. As the thermal isolation is maintained, the lifetime and durability of the electrolytic capacitors 401 is enhanced.

In FIG. 8C, a third example configuration of the power electronic system 200 assembly is disclosed. In accordance with the third example configuration, the heat sink 801 is thermally coupled only to the second area 209 of the power electronic system 200 assembly i.e., a center of the extrusion 807 is removed to thermally isolate the first set of electronic components of the first area 207 from the second set of electronic components and the third set of electronic components of the second area 209. The heat sink 801 is configured to be attached to the second area 209 in an orientation relative to a portion of the enclosure 803 covering the second area 209. According to an embodiment, the plastic insulation 805 for the thermal isolation is also provided in the third configuration. The plastic insulation 805 substantially separates the enclosure 803 into two portions such that the heat generated by the second set of electronic components and the third set of electronic components in the second area 209 does not affect the first set of electronic components in the first area 207. Accordingly, the third example configuration of the power electronic system 200 assembly helps in managing the thermal heat within the power electronic system 200 assembly such that the heat generated by the second set of electronic components and the third set of electronic components in the second area 209 does not affect the first set of electronic components and thus the first set of electronic components are thermally isolated from the second set of electronic components and the third set of electronic components by using the at least one process of the conduction and the convection. The reference of the first area 207 and the second area 209 can be referred to through FIG. 8A.

In FIG. 8D, a fourth example configuration of the power electronic system 200 assembly is disclosed. In accordance with the fourth example configuration, the heat sink 801 is thermally coupled to each of the first area 207 and the second area 209 of the power electronic system 200 assembly i.e., the center of the extrusion is not removed. The heat sink 801 is configured to be attached to the first area 207 and the second area 207 in an orientation relative to a portion of the enclosure 201 covering the first area 207 and the second area 209. The reference of the first area 207 and the second area 209 can be referred to through FIG. 8A. In an embodiment, the fourth example configuration is different from the first, second, and the third example configuration of the power electronic system 200 assembly in view of the plastic insulation. According to an embodiment, a plastic cap 809 is provided which is in contact with the heat sink 801 and encasing the first area 207 on three sides. In an embodiment, the first area separates from the second area on a fourth side. Accordingly, the fourth example configuration of the power electronic system 200 assembly helps in managing the thermal heat within the power electronic system 200 assembly accurately and effectively to thermally isolate the first set of the electronic components from the second set of electronic components by using the at least one process of the conduction and the convection.

In FIG. 8E, a fifth example configuration of the power electronic system 200 assembly is disclosed. In accordance with the fifth example configuration, the heat sink 801 is thermally coupled only to the second area 209 of the Power electronic system 200 assembly i.e., the center of the extrusion 807 is removed. The heat sink 801 is configured to be attached to the second area 209 in an orientation relative to a portion of the enclosure 803 covering the second area 209. Further, the plastic insulation i.e. the plastic cap 809 for the thermal isolation member is also provided. The fifth example configuration is different from the first, second, third, and the fourth example configuration of the power electronic system 200 assembly in view of the plastic cap 809 is encasing the first area 207 on three sides and is not in contact with the heat sink 801. Further, the first area 207 separates from the second area on a fourth side such that the fourth side of the first area 207 is not in contact with the heat sink 801. The reference of the first area 207 and the second area 209 can be referred to through FIG. 8A.

In FIG. 8(F), a sixth example configuration of the power electronic system 200 assembly is disclosed. In accordance with the sixth example configuration, the heat sink 801 is thermally coupled only to the second area 209 of the Power electronic system 200 assembly i.e., the center of the extrusion 807 is removed. The heat sink 801 is configured to be attached to the second area 209 in an orientation relative to a portion of the enclosure 803 covering the second area 209. Further, the plastic insulation i.e. the plastic cap 809 for thermal isolation member is also provided in the sixth configuration. The sixth example configuration is different from the first, second, third, fourth, and the fifth example configuration of the Power electronic system 200 assembly in view of a foam insulation 811 disposed between the first area 207 and the second area 209, from the fourth side of the first area 207, where the foam insulation is enclosed by the plastic cap 809. Accordingly, the sixth example configuration of the power electronic system 200 assembly helps in providing additional safeguard to the first set of electronic components from the heat generated by the second set of electronic components, and thus providing enhanced thermal isolation to the first area 207 of the power electronic system 200 assembly. Further, the plastic cap includes a clearance on all sides to prevent interference with an attachment of a central aluminum extrusion to a mounting surface, and the clearance is approximately 0.5 mm. The reference of the first area 207 and the second area 209 can be referred to through FIG. 8A.

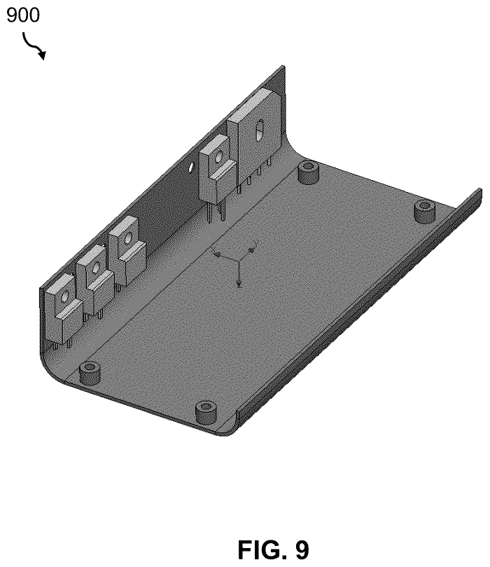

FIG. 9 illustrates a 3D view of a wrap round heat sink, according to an embodiment of the present disclosure. According to an embodiment, a wrap round heat sink 900 is provided around the first set of electronic components along with the second set of electronic components and the third set of electronic components. According to an embodiment, the wrap around heat sink 900 is thermally coupled with the first area 207 an the second area 209. For the sake of brevity, a 3D view of the wrap around heat sink is depicted. Further, the power electronic system 200 system can be referred to through the FIG. 4A. In an embodiment, the surface of the wrap around heatsink 900 plate may be covered with an insulating sheet such as Kapton tape or Mylar to electrically isolate the wrap around heatsink 900 plate from the first set of electronics components and the second set of electronics components. According to an embodiment, the first set of electronics components and the second set of electronics components may interface with the wrap around heatsink 900 via thermal conductive thermal pad such as Sil-Pad. Such pads reduce the thermal contact resistance.

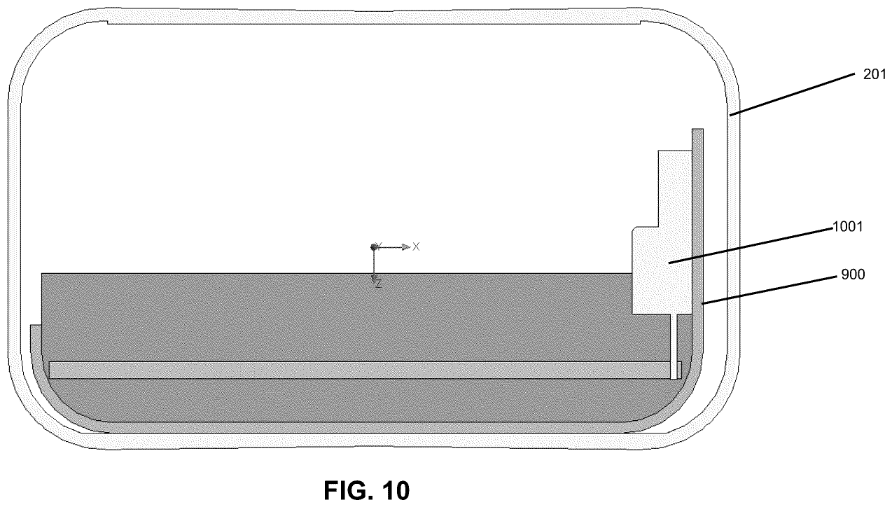

FIG. 10 illustrates a cross-sectional view of the power electronic system with a wrap around heat sink, according to an embodiment of the present disclosure. According to an embodiment, the power electronic system 200 assembly is enclosed in the enclosure 201. As depicted the wrap around heat sink 900 wraps around to the bottom of the enclosure 201. In a non-limiting example, the wrap around heat sink 900 can be of 1 mm thick aluminum sheet metal that can be bent to into a wrap around shape. Further, the components 1001 (i.e. the first set of components and the second set of components) such as MOSFET, diodes, bridge are attached to the wrap around heatsink 900. As can be seen, the warp around the heatsink 900 makes contact with the bottom of the enclosure 201 over a large area, which effectively reduces the thermal interface resistance due to the increased contact area. The disclosed design optimizes the heat transfer process within the system. Further, the interface between the potting and the enclosure may involve the use of an electrical insulator sheet, such as Mylar or insulating paper, which functions to surround the entire electronics assembly for the purpose of electrical isolation from the metal enclosure. This arrangement not only minimizes the thermal path but also significantly reduces the thermal resistance of the components to the enclosure 201, thereby enhancing the overall thermal management and electrical safety of the system.

Table 1 illustrates an example temperature measured across each component of FIG. 4B in case of a wrap around heat sink is implemented in the power electronic system

TABLE 1
Vertical Driver at 250W, Ambient Air = 60° C.

| | | | Improvement Over as |
|---|---|---|---|
| | Tₘₐₓ | Tₘₐₓ-T_{A} | compared to conventional |
| Item | (° C.) | (° C.) | art (° C.) |
| EC1 | 96.3 | 36.3 | −5.9 |
| EC3 | 88.9 | 28.9 | 0.6 |
| T1 | 99.2 | 39.2 | −2.7 |
| T2 | 109.2 | 49.2 | −3.7 |
| Q1 | 91.8 | 31.8 | −5.8 |
| Q2 | 97.8 | 37.8 | −9.3 |
| D5 | 94.8 | 34.8 | −8.7 |
| D2 | 92.9 | 32.9 | −9.8 |
| BD1 | 90.4 | 30.4 | −6.0 |
| NTC1 | 197.5 | 37.5 | 3.0 |
| NTC2 | 101.1 | 41.1 | −0.7 |
| Enclosure | 82.7 | 22.7 | 0.1 |
| HSK | 91.7 | 31.7 | −9.6 |

According to an example embodiment, consider that EC1 is surrounded by components Q1, Q2, D5, D2, and BD1 and the wrap around heatsink 900 is directly attached to components Q1, Q2, D5, D2, and BD1. As can be seen from the Table 1 the electrolytic capacitor EC1 indirectly benefited as the surrounding components Q1, Q2, D5, D2, and BD1 becomes cooler. Further, the wrap-around heatsink 900 directly benefits Q1, Q2, D5, D2, and BD1 as they are attached to it. In an embodiment, the negative sign depicts that the temperature measured is cooler as compared to the temperature measured without the disclosed configuration.

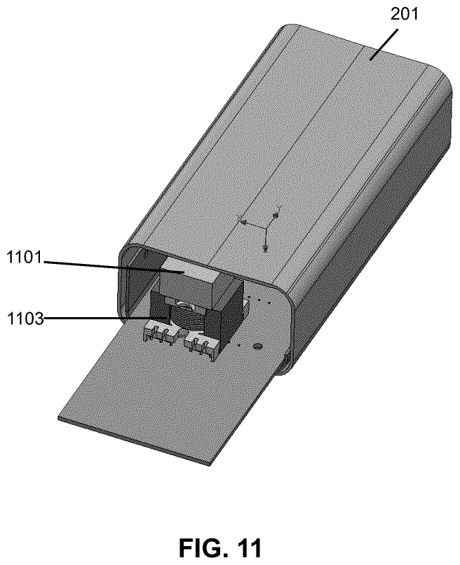

FIG. 11 illustrates a 3D view of the power electronic system with the heat sink associated with inductors and transformers, according to an embodiment of the present disclosure. According to some embodiments, the heat sink 1101 is mounted on the top of the inductors and the transformers 1103. In an embodiment, the heat sink 1101 makes thermal contact with the top of the enclosure 201.

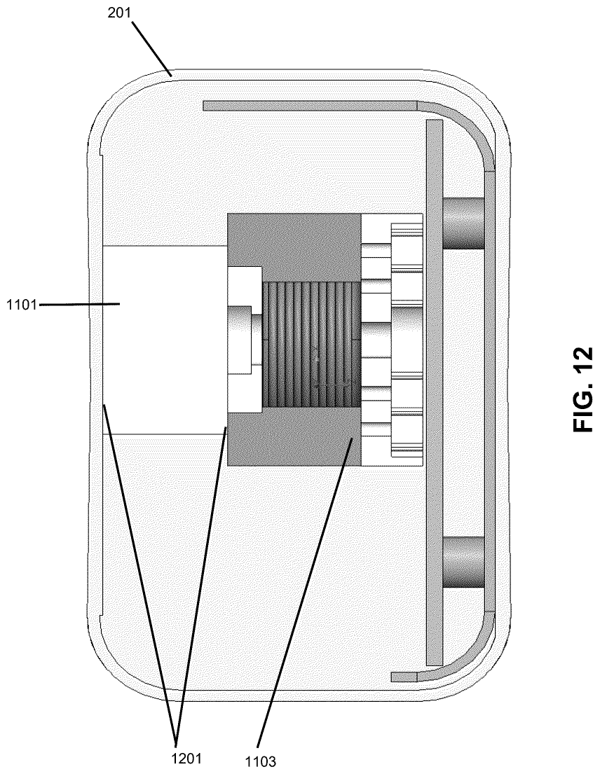

FIG. 12 illustrates a cross-sectional view of the Power electronic system with the heat sink associated with inductors and transformers, according to an embodiment of the present disclosure. As can be seen, the heat sink 1101 is mounted on the top of the inductors and the transformers 1103. The heat sink 1101 makes thermal contact with the top of the enclosure 201. The heat sink 1101 transfers the heat more directly to the top of the extrusion of the enclosure 201. Further, the interface between the thermal pad 1201 and the enclosure 201 may be an electrical insulator sheet (not shown) such as Mylar or insulating paper. The insulator sheet may surround the entire electronics to electrically isolate from the metal enclosure 201. The thermal Interface pad such as “Sil-Pad” reduces thermal interface resistance and also provides a degree of electrical insulation. The arrangement significantly reduces the thermal path (thermal resistance) from components to the enclosure 201.

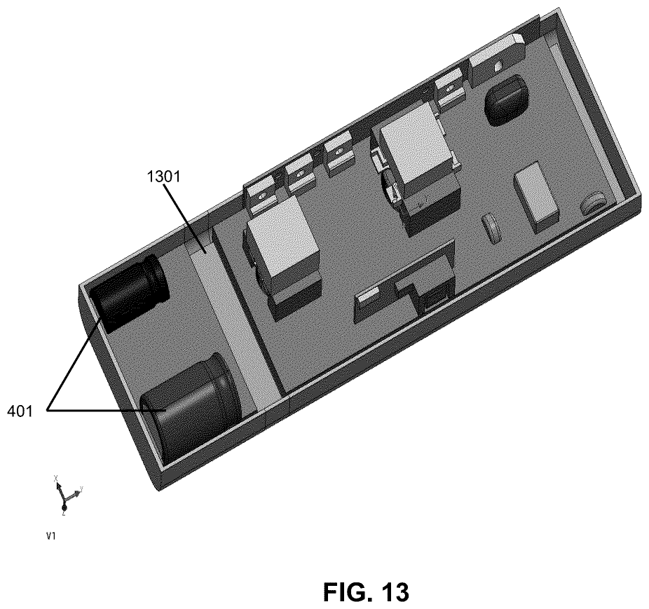

FIG. 13 illustrates a 3D view of the power electronic system with a gap created in potting to provide a degree of thermal conduction, in accordance with an embodiment of the present disclosure. According to an embodiment, a gap 1301 is created in the potting of the enclosure to provide a degree of thermal conduction separation internal to the enclosure 201. In an embodiment, the gap 1301 created in potting doesn't short circuit the first area 207 and the second area 209, so the temperature of the enclosure 201 surrounding the first area 207 and the second area 209 are not similar.

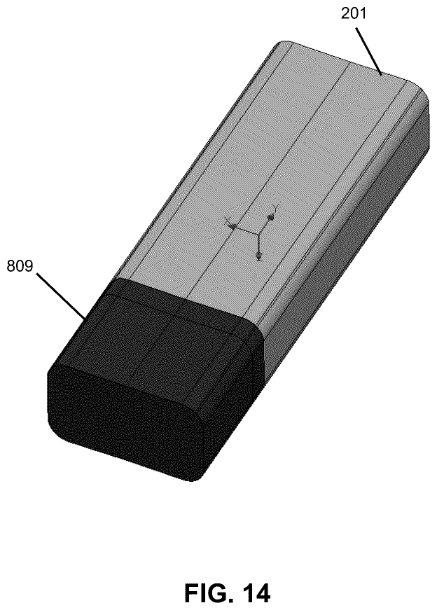

FIG. 14 illustrates a 3D view of the power electronic system with a plastic cap encapsulating the first area, according to an embodiment of the present disclosure. Internally, the potting gap provides thermal conduction isolation between the first area 207 and the second area 209. Since the potting does not fill to the top of the enclosure 201 there can still be air convection between the two areas. According to the current embodiment, the plastic cap 809 as disclosed in FIG. 8E is provided encapsulating the first area 207. The plastic cap 809 provides the thermal conduction isolation from the aluminium enclosure 201 of the second area 209.

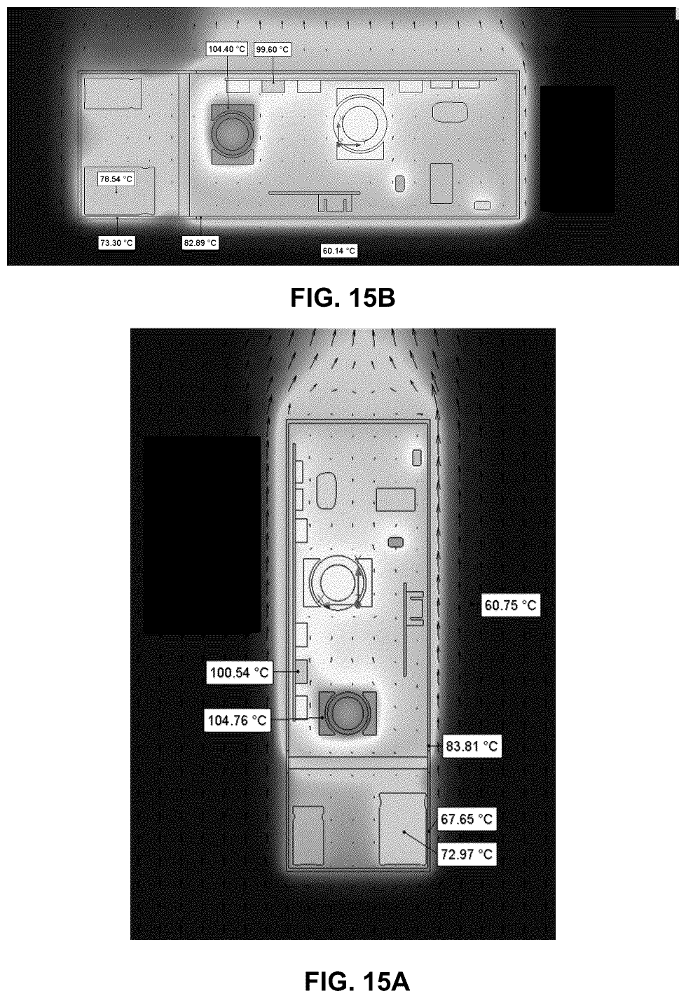

FIGS. 15A and 15B illustrate a thermal analysis of the power electronic system with a plastic cap in a case of vertical and horizontal orientation of the Power electronic system relative to the enclosure respectively, according to an embodiment of the present disclosure. Referring to FIG. 15A, as the Aluminium enclosure encloses externally the second area 209, the temperature at the second area 209 is found to be approximately 83.63° C. Further, as the first area 207 encloses the plastic cap 809, and the enclosure encloses externally the second area 209, the temperature at the second area 209 is measured to be approximately 74.3° C. This is lower than the second area 209. Thus, it is evident that the thermal isolation is working. Table 2 illustrates the temperature measured at various components as shown in FIG. 4B.

Referring to FIG. 15B, as the Aluminium enclosure encloses externally the second area 209, the temperature at the second area 209 is found to be approximately 74.43° C. Further, as the first area 207 encloses the plastic cap 809, and the enclosure encloses externally the second area 209, the temperature at the second area 209 is measured to be approximately 74.43° C. This is lower than the second area 209. Thus, it is evident that the thermal isolation is working. Table 3 illustrates the temperature measured at various components as shown in FIG. 4B.

TABLE 2
Driver at 250W, Ambient Air = 60° C.

| | | | Improvement as |
|---|---|---|---|
| | | | compared to the |
| | Tₘₐₓ | Tₘₐₓ-T_{A} | conventional art |
| Item | (° C.) | (° C.) | (° C.) |
| EC1 | 80.5 | 20.5 | −3.6 |
| EC3 | 74.7 | 14.7 | −6.8 |
| T1 | 97.6 | 37.6 | 4.9 |
| T2 | 104.8 | 44.8 | 3.8 |
| Q1 | 94.5 | 34.5 | 4.5 |
| Q2 | 100.3 | 40.3 | 4.7 |
| D5 | 97.3 | 37.3 | 4.5 |
| D2 | 95.3 | 35.3 | 4.7 |
| BD1 | 93.2 | 33.2 | 4.5 |
| NTC1 | 100.8 | 40.8 | 4.8 |
| NTC2 | 103.3 | 43.3 | 4.9 |
| S1 Enclosure | 85.9 | 25.9 | 4.7 |
| HSK | 94.4 | 34.4 | 4.6 |

TABLE 3
Vertical Driver at 250W, Ambient Air = 60° C.

| | | | Improvement as |
|---|---|---|---|
| | Tₘₐₓ | Tₘₐₓ-T_{A} | compared to the |
| Item | (C) | (° C.) | conventional art (° C.) |
| EC1 | 81.0 | 21.0 | −3.7 |
| EC3 | 77.9 | 17.9 | −3.9 |
| T1 | 95.6 | 35.6 | 1.4 |
| T2 | 103.5 | 43.5 | 1.7 |
| Q1 | 92.9 | 32.9 | 1.7 |
| Q2 | 99.0 | 39.0 | 2.3 |
| D5 | 96.1 | 36.1 | 2.4 |
| D2 | 93.9 | 33.9 | 2.1 |
| BD1 | 91.5 | 31.5 | 1.6 |
| NTC1 | 98.8 | 38.8 | 1.1 |
| NTC2 | 101.2 | 41.2 | 1.3 |
| A1 Enclosure | 84.5 | 24.5 | 2.2 |
| HSK | 93.1 | 33.1 | 2.3 |

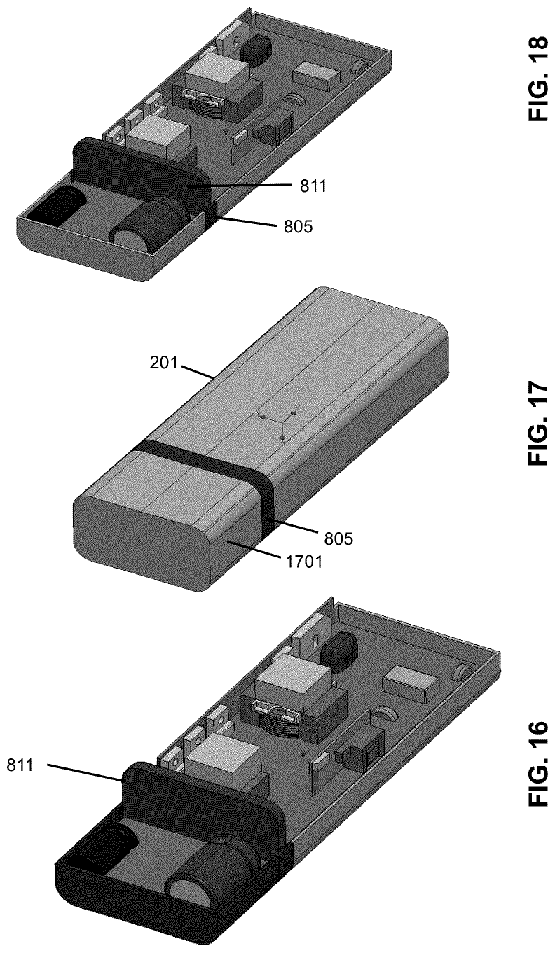

FIG. 16 illustrates a 3D view of a foam disposed in the gap of the Power electronic system, according to an embodiment of the present disclosure. According to an embodiment, the insulation foam 811 as described in FIG. 8F is disclosed. Internally, the potting gap provides the thermal conduction isolation between the first area 207 and the second area 209. The addition of a physical barrier such as insulation foam 811 prevents convection between the first area 207 and the second area 209. In an embodiment, there may be holes in the foam to allow for the passage of the PCB, wiring, etc. between the first area 207 and the second area 209.

In an embodiment, adding the convection barrier, like the gap in the potting and disposing of the insulation foam in the gap, the benefits to EC1/EC3 in horizontal orientation are larger than in vertical orientation. This is because in vertical orientation hot air rises creating a natural convection barrier, however in the horizontal such barrier is created by the addition of the barriers.

FIG. 17 illustrates a 3D view of a power electronic system encapsulated with a metal isolated cap, according to an embodiment of the present disclosure. Referring to FIG. 17, according to an embodiment, the second area 209 is externally surrounded by an aluminium enclosure 201. A plastic spacer 805 as depicted in FIGS. 8B and 8C for thermally isolating via the conduction process the second area 209 enclosure from the first area 207. Further, the first Area 207 is externally surrounded by an aluminium enclosure (Cap) 1701. This metal allows for better conduction of heat inside of area to external air.

FIG. 18 illustrates a 3D view of the foam and the spacer disposed in the gap of the power electronic system, according to an embodiment of the present disclosure Internally the potting gap is provided for thermal conduction isolation between the first area 207 and the second area 209. The addition of the physical barrier such as insulation foam 811 prevents convection between the first area 207 and the second area 209. There may be holes in the foam to allow for the passage of PCB, wiring, etc. between first area 207 and the second area 209. In an embodiment, the physical convection barrier aligns in the same position as the plastic spacer 805 for thermally isolating the first area and the second area enclosures.

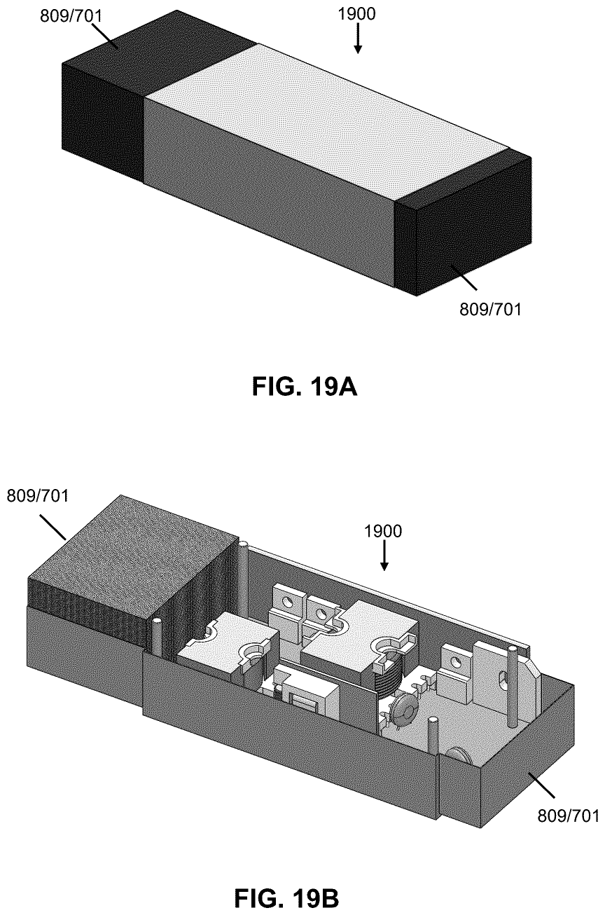

FIG. 19A and FIG. 19B illustrate a 3D view of a power electronic system box, in accordance with an embodiment of the present disclosure. The driver box 1900 includes plastic end caps 809/701 and an aluminum center extrusion in a single piece. The plastic end caps 809/701 are inserted into the long end and the short end of the driver box 1900 by press-fitting the caps.

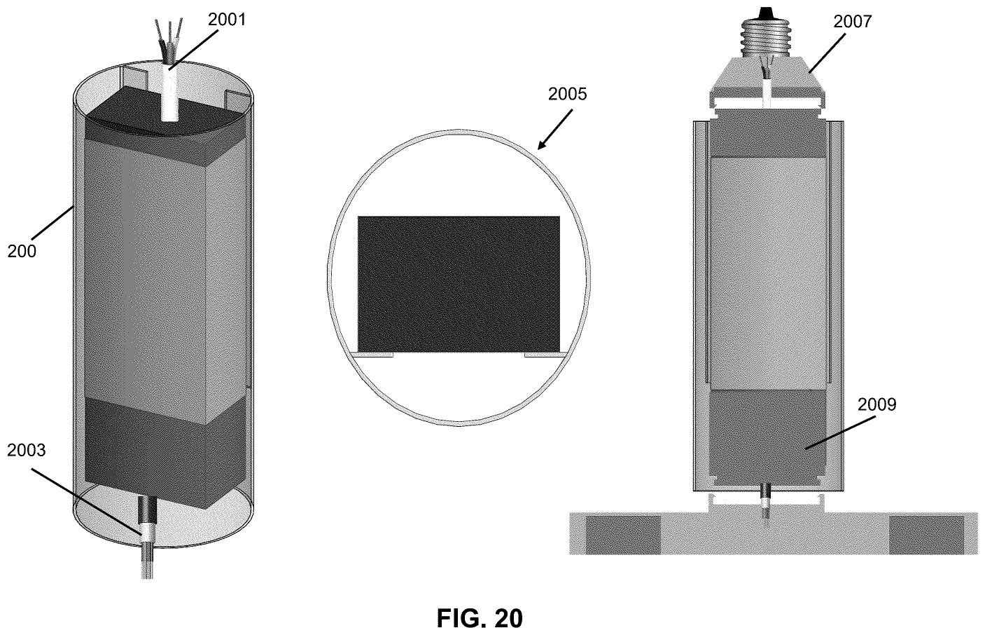

FIG. 20 illustrates an exemplary 3D view depicting design and installation of various components of the power electronic system assembly in an LED lighting system, in accordance with an embodiment of the present disclosure. The power electronic system 200 (LED driver) assembly includes various other components such as an input cable 2001, output cable 2003, and other components that need to be attached securely while maintaining an Ingress Protection (IP65) rating. In the context of the lighting systems, light fixtures that are rated IP65 and above are considered to be waterproof and are suitable for both indoor and outdoor use. Block 2005 illustrates how the heat sink is attached to the center extrusion. In an implementation, each of the lens, the sensors, and Ex39 2007 attaches directly to the driver and not to round extrusion and needs to maintain the IP65 rating. The Ex39 2007 stands for Explosion-proof and 39 indicates a type of base or socket design. The Ex39 typically refers to a specific type of lamp base or socket standard used in lighting fixtures, especially in industrial and hazardous area lighting. Block 2009 shows that lens/sensor attaches directly to the driver and not round extrusion IP 65.

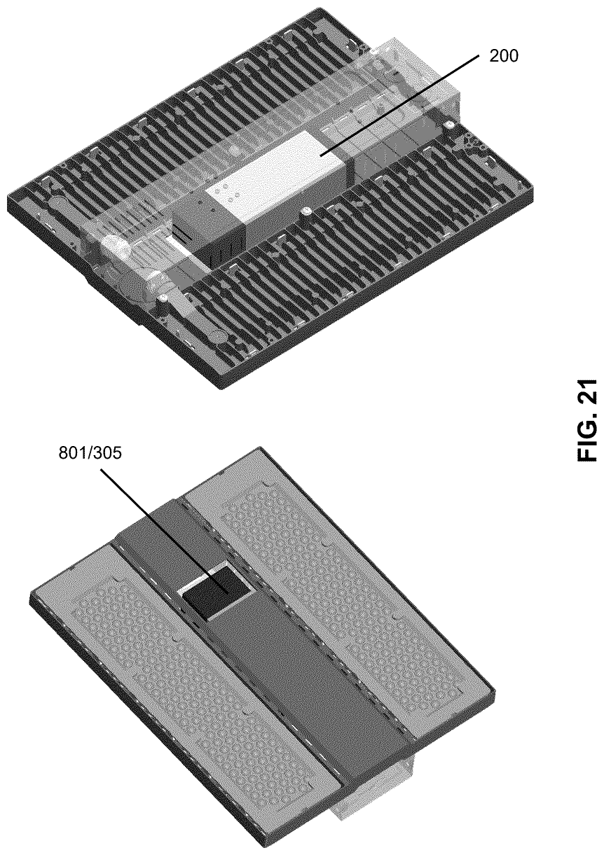

FIG. 21 illustrates an exemplary 3D view depicting the design and installation of various components of the power electronic system assembly in a linear high bay lighting system, in accordance with an embodiment of the present disclosure. As shown in FIG. 21, exposing the heat sink of the power electronic system 200 assembly in the linear high bay lighting system to cool air is ideal for optimal thermal management. However, even if the heat sink 801/305 is not fully exposed, it can still provide effective cooling with proper design and installation. In line with the previous embodiments, the present embodiment discloses an arrangement of the LEDs and the power electronic system designed to ensure that heated air from the LEDs does not substantially pass through the driver.

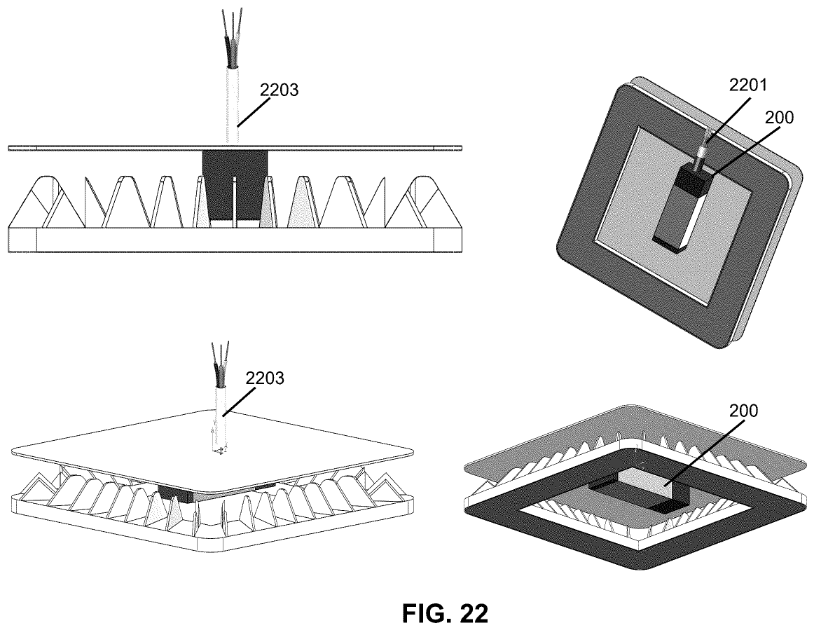

FIG. 22 illustrates an exemplary 3D view depicting the design and installation of various components of the power electronic system assembly in an LED-based canopy setup, in accordance with an embodiment of the present disclosure. FIG. 22 illustrates that the power electronic system 200 (LED driver) assembly is mounted against the ceiling and airflow temperature is greater than 90° C. The output cable 2201 is attached directly to the LED 200 and not exposed to the cool air, and the input cable 2203 is taken out of the back of LED fixture. In line with the previous embodiments, the present embodiment also discloses an arrangement of the LEDs and the power electronic system designed to ensure that heated air from the LEDs does not substantially pass through the power electronic system.

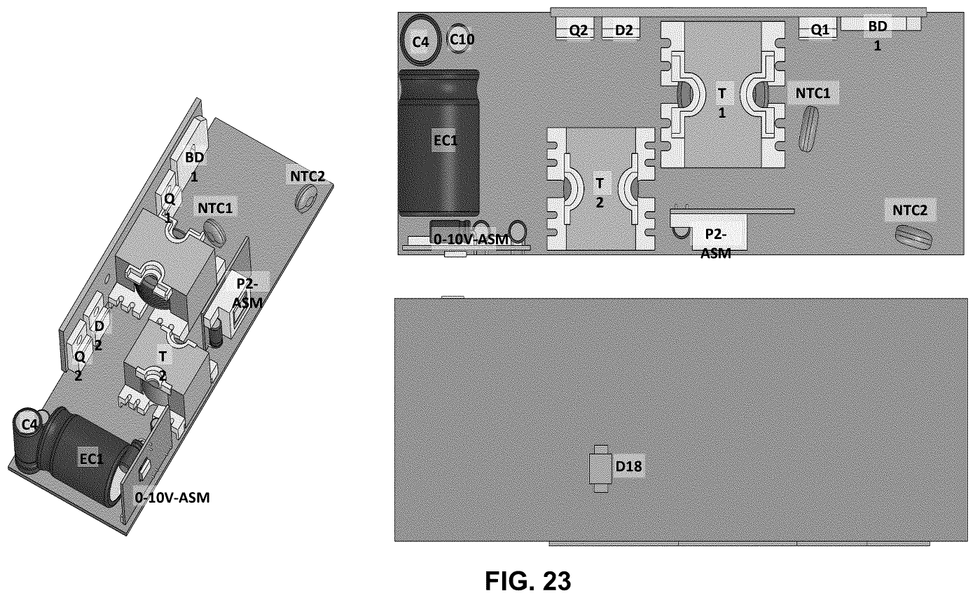

FIG. 23 illustrates an example of a layout depicting locations of key components of the power electronic system, in accordance with an embodiment of the present disclosure. The components are sized and cut to fit the PCB and mounted to appropriate locations on the PCB.

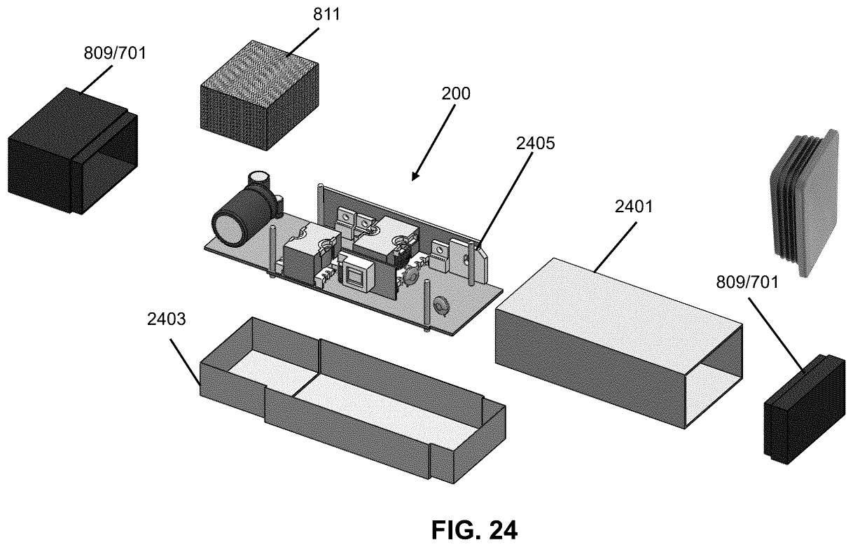

FIG. 24 illustrates an exploded view of the power electronic system assembly including a thermal management mechanism, in accordance with an embodiment of the present disclosure. The power electronic system assembly includes the foam insulation 809/701, the PCB of the power electronic system assembly, an extruded housing 2401, Mylar 2403, plastic insulations 809/701 provided at each of long and short ends of the enclosure, and plastic standoffs 2405 provided at two ends of the enclosure.

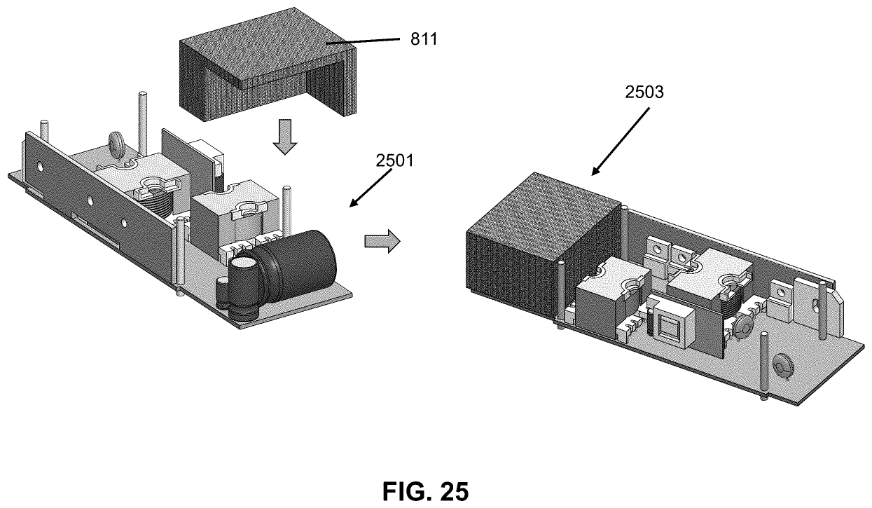

FIG. 25 through FIG. 30 illustrate sequential steps of forming the power electronic system assembly including the thermal management mechanism, in accordance with an embodiment of the present disclosure. At step 1, the foam insulation 811 is mounted at an end portion of the PCB as shown in the blocks/views 2501 and 2503 of FIG. 25. The foam insulation 811 may be a thermoplastic or a thermoset material. The foam insulation 811 is cut and shaped to fit into the PCB's rough or textured surface.

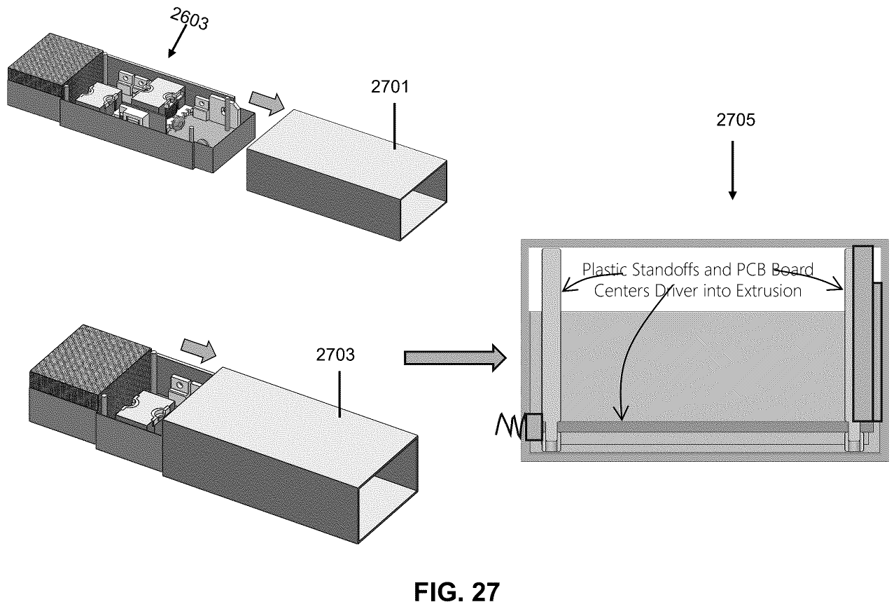

Further, at step 2, the PCB integrated with the foam insulation is assembled or wrapped in Mylar (2403) (a type of polyester film) at block 2601 to ensure excellent electrical insulation and shock resistance to get the assembled PCB integrated with the foam insulation at block 2603. The foam insulation helps absorb stress and friction, while the Mylar prevents moisture and corrosion from reaching the PCB. Further, at step 3, the PCB Mylar assembly is then slid into extruded housing 2701 and 2703 as shown in FIG. 27. The extruded housing refers to a profile shaped to accommodate the PCB Mylar assembly and is typically made from materials like Aluminium, designed to house and protect the internal components. The extruded housing provides structural support and may also serve as a heat sink to dissipate heat generated by the power electronic system. Block 2705 shows the internal view of the plastic standoffs and PCB board centers driver into extrusion after sliding.

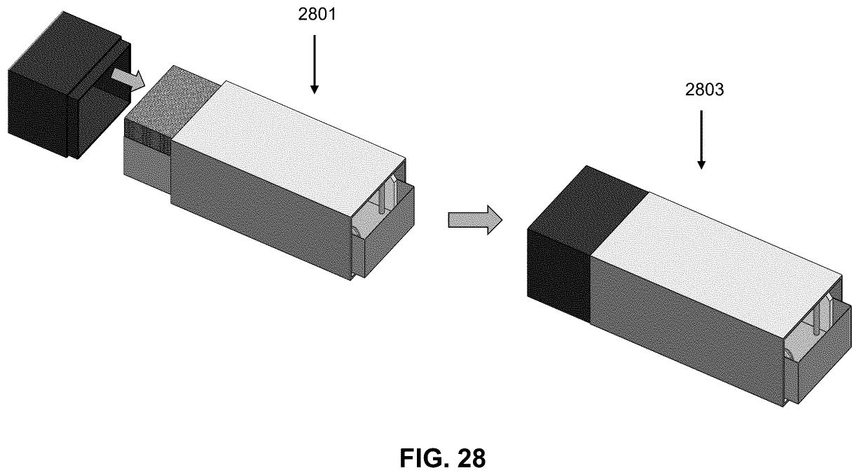

Further, at step 4, as shown in FIG. 28, the assembly is further encased (at a long end) with the plastic cap through a press fit at block 2801. The plastic cap is in contact with the first heat sink and encases the first area on three sides. The plastic cap may be spaced apart from the first heat sink to enhance thermal isolation and encloses the foam insulation. The final output is shown in block 2803.

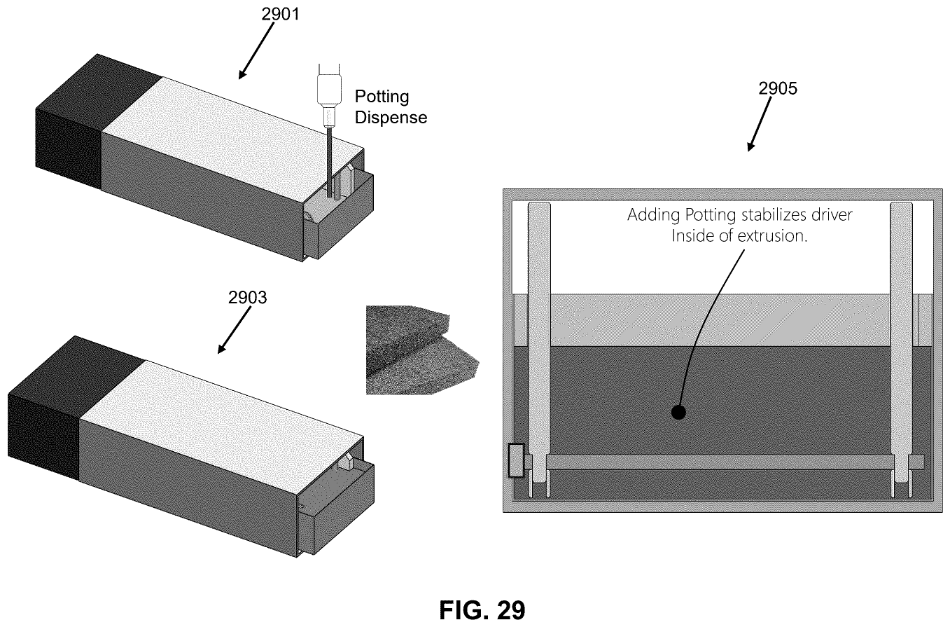

Further, at step 5, as shown in blocks 2901 and 2903 of FIG. 29, a potting compound is dispensed inside the extruded housing, which stabilizes the driver. Potting refers to a process of encapsulating an electronic component (like an LED package) in a coating of insulating material, also known as a potting compound. This encapsulation provides protection from environmental factors such as moisture, dust, and thermal stress. The potting compound is usually a transparent or translucent material that allows keeping the electrical components inside secure and isolated. Block 2905 shows an interval view of the housing after dispensing the potting.

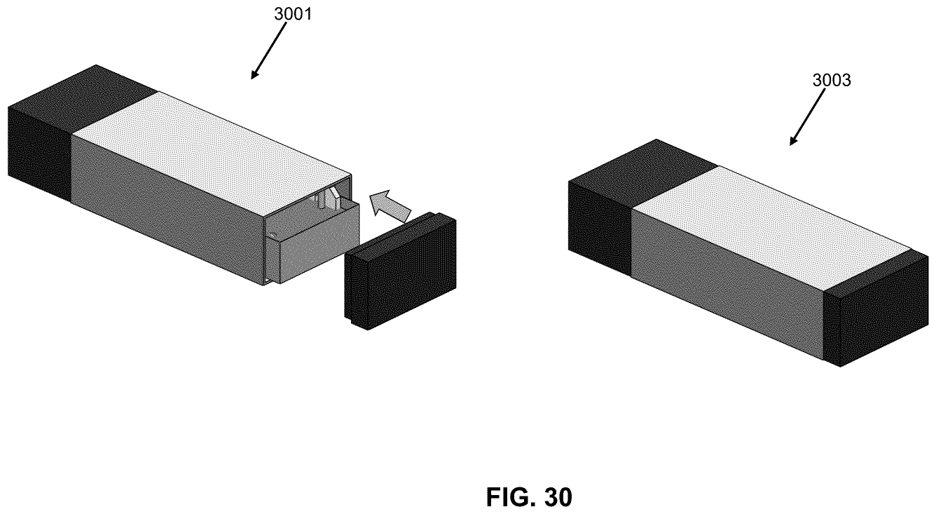

Further, at step 6, at blocks 3001 and 3003 of FIG. 30, the assembly is now encased at the other end (short end) with the plastic cap through press fit. The plastic cap encases the second area on three sides. The assembly is then left for some time to allow curing of the potting compound.

To summarize, the invention discloses thermal management and isolation techniques using convection and conduction. These strategies include both internal and external measures as follows:

Internal Measures within the Enclosure:

Reducing Conduction and Convection: The design discloses a mechanism to minimize heat transfer through direct contact and air movement inside the enclosure.

Spatial Separation: Placing first area and second area at a sufficient distance from each other, even without a physical barrier, helps maintain a temperature difference.

Physical Barriers: Using insulation materials within the enclosure can prevent heat from moving between the first area and the second area through convection.

Vertical Orientation: Positioning the second area above first area can naturally keep hot air in the second area since hot air rises up. This setup provides convection isolation without needing a physical barrier.

Thermal Barriers within the Enclosure: Incorporating thermal barriers that separate the first area and the second area within the enclosure itself can reduce heat transfer through conduction.

### External Measures Outside the Enclosure:

Separate Airflows: Designing the airflow paths so that air flows are kept apart for the first area and the second area.

Sequential Airflow: Ensuring that air first flows through the first area before reaching the second area, which means that the first area receives cooler air initially.

Heatsink or Mounting: Using the heatsinks or mountings that do not create a thermal shortcut between the first area and the second area to avoid unwanted heat transfer.

By applying these embodiments, the overall design will achieve thermal isolation, resulting in a temperature difference between the first Area and the second area of more than 5° C.

A person skilled in the art will appreciate that multiple thermal management mechanisms are incorporated in the present invention. However, other embodiments could be implemented without utilizing one or more of these mechanisms.

A person skilled in the art will appreciate that alternative components can be utilized in the described embodiments. For instance, instead of using plastic or foam for insulation, other materials known in the art can be employed.

The foregoing detailed description of the certain exemplary embodiments has been provided for the purpose of explaining the principles of the invention and its practical application, thereby enabling others skilled in the art to understand the invention for various embodiments and with various modifications as are suited to the particular use contemplated. This description is not necessarily intended to be exhaustive or to limit the invention to the exemplary embodiments disclosed. Any of the embodiments and/or elements disclosed herein may be combined with one another to form various additional embodiments not specifically disclosed. Accordingly, additional embodiments are possible and are intended to be encompassed within this specification and the scope of the appended claims. The specification describes specific examples to accomplish a more general goal that may be accomplished in another way.

As used in this application, the terms “front,” “rear,” “upper,” “lower,” “upwardly,” “downwardly,” and other orientational descriptors are intended to facilitate the description of the exemplary embodiments of the present disclosure and are not intended to limit the structure of the exemplary embodiments of the present disclosure to any particular position or orientation. Terms of degree, such as “substantially” or “approximately” are understood by those of ordinary skill to refer to reasonable ranges outside of the given value, for example, general tolerances associated with manufacturing, assembly, and use of the described embodiments.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What we claimed is:

1. A power electronic system comprising:
at least one enclosure enclosing at least a first area (207) and a second area (209), wherein the first area (207) has a lower temperature than the second area (209);
the first area (207) comprising a first set of electronic components (405); and
the second area (209) comprising a second set of electronic components (407) and a third set of electronic components (409), wherein
the second set of electronic components (407) receives electrical power from a power source, and provides output to the first set of electronic components (405),
the third set of electronic components (409) receives the input from the first set of electronic components (405) and provides the output to a load,
the first set of electronic components (405) comprises at least one thermal-sensitive component that is more temperature-sensitive than either of the second set of electronic components (407) and the third set of electronic components (409), and
the first area (207) is thermally isolated from the second area (209).

2. The power electronic system of claim 1, wherein the first area (207) does not overlap with the second area (209).

3. The power electronic system of claim 1, wherein a temperature of the first area (207) is at least 5 degrees Celsius lower than the second area (209).

4. The power electronic system of claim 1, wherein the first set of electronic components (405) comprises at least one electrolytic capacitor.

5. The power electronic system of claim 1 comprises one of an LED driver, a solar inverter, an AC-AC power converter, an AC-DC power converter, a DC-to-DC power converter, a DC-to-AC power converter, or a power amplifier.

6. The power electronic system of claim 1, wherein the at least one enclosure comprises a first enclosure and a second enclosure, the first enclosure enclosing the first area (207) and the second enclosure enclosing the second area (209).

7. The power electronic system of claim 7, wherein the first enclosure is thermally isolated from the second enclosure by using at least one process of conduction and convection.

8. The power electronic system of claim 1, wherein the second set of electronic components (407) and the third set of electronic components (409) generate a majority of heat in the power electronic system.

9. The power electronic system of claim 1, wherein the first set of electronic components (405) generates less than 10% of a total heat generated by the power electronic system.

10. The power electronic system of claim 6, wherein the first enclosure receives a first airflow, and the second enclosure receives a second airflow.

11. The power electronic system of claim 10, wherein a source of the first airflow is different from a source of the second airflow.

12. The power electronic system of claim 10, wherein the first enclosure receives the first airflow, and the second enclosure receives the second airflow along a part of the first airflow that is received via the first enclosure, based on a positional placement of the first enclosure corresponding to the second enclosure, wherein the first enclosure comprises the first set of electronic components (405) and the second enclosure comprises the second set of electronic components (407) and the third set of electronic components (409).

13. The power electronic system of claim 12, wherein the positional placement comprises vertical positional placement, horizontal positional placement, and diagonal positional placement.

14. The power electronic system of claim 1, wherein the second set of electronic components (407) comprise an input stage of a Switch-Mode Power Supply (SMPS), the third set of electronic components (409) comprise an output stage providing the SMPS as the output to the load, and the first set electronic components (405) comprise components at the center stage electrically between the second set of electronic components (407) and the third set of electronic components (409).

15. The power electronic system of claim 14 wherein the first set of electronic components (405) comprises at least one electrolytic capacitor.
